(19) United States
(12) Patent Application Publication
(10) Pub. No.: US 2026/0082982 A1
(43) Pub. Date: Mar. 19, 2026

(54) INTEGRATED CIRCUIT PACKAGE AND METHODS FOR FABRICATION THEREOF

(71) Applicant: TAIWAN SEMICONDUCTOR MANUFACTURING COMPANY, LTD., Hsinchu (TW)

(72) Inventors: Yi Chen HO, Taichung (TW); Hao-Yun HUANG, Hsinchu (TW); Sian-Chen SHEU, Hsinchu (TW)

(21) Appl. No.: 19/058,161

(22) Filed: Feb. 20, 2025

Related U.S. Application Data
(60) Provisional application No. 63/695,037, filed on Sep. 16, 2024.

(51) Int. Cl. H01L 23/31; H01L 21/304; H01L 21/56; H01L 23/00; H01L 25/00; H01L 25/11

(52) U.S. Cl. CPC H10W 74/121; H10P 52/00; H10W 74/01; H10W 90/00; H10W 90/722; H10W 90/732

(57) ABSTRACT

Embodiments of the present disclosure provide IC dies with rounded corners. In some embodiments, the IC die is a SOIC (system on integrated chip). The rounded corners prevent tip discharge which may adversely affect circuit structure of the SOIC. The IC dies with the rounded corners improve quality of gap filling material in IC packages, for example, reducing cracks in the gap filling material.

### CROSS-REFERENCE TO RELATED APPLICATIONS

This application claims priority to the U.S. Provisional Patent Application Serial. No. 63/695,037, filed Sep. 16, 2024, which is incorporated by reference in its entirety.

### BACKGROUND

Semiconductor devices are used in a variety of electronic applications, such as personal computers, cell phones, digital cameras, and other electronic equipment, as examples. Semiconductor devices are typically fabricated by sequentially depositing insulating or dielectric layers, conductive layers, and semiconductive layers of material over a semiconductor substrate, and patterning the various material layers using lithography to form circuit components and elements thereon. Dozens or hundreds of integrated circuits are typically manufactured on a single semiconductor wafer, and individual dies on the wafer are singulated by cutting between the integrated circuits along a scribe line. The individual dies are typically packaged separately, in multi-chip modules, or in other types of packaging, for example.

Three-dimensional integrated circuits (3DICs) are a relatively recent development in semiconductor packaging in which multiple semiconductor dies are stacked upon one another, such as package-on-package (PoP) and system-in-package (SiP) packaging techniques. A 3DIC may provide improved integration density and other advantages, such as faster speeds and higher bandwidth, because of the decreased length of interconnects between the stacked dies, as examples.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, and 1C schematically illustrate an integrated circuit package according to embodiments of the present disclosure.

FIG. 2 is a flow diagram of forming of dies with rounded edges according to embodiments of the present disclosure.

FIGS. 3A, 3B, 3C, 3D, 3E, 3F, 3G, 3H, 3I, 3J, and 3K schematically demonstrate various processing stages during fabrication of dies rounded edges according to embodiments of the present disclosure.

FIGS. 3L and 3M schematically IC dies according to embodiments of the present disclosure.

FIG. 4 is a schematic Figure demonstrate various processing stages during fabrication of dies rounded edges according to embodiments of the present disclosure.

FIGS. 5A, 5B, 5C, 5D, 5E, 5F, 5G, 5H, 5I, 5J, 5K, 5M, 5N, and 5O schematically demonstrate various processing stages during fabrication of an integrated circuit package according to embodiments of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will be described with respect to embodiments in a specific context, namely an integrated circuit package. Other embodiments may also be applied, however, to other electrically connected components, including, but not limited to, package-on-package assemblies, die-to-die assemblies, wafer-to-wafer assemblies, die-to-substrate assemblies, die-to-wafer assemblies, in assembling packaging, in processing substrates, interposers, or the like, or mounting input components, boards, dies or other components, or for connection packaging or mounting combinations of any type of integrated circuit or electrical component. Various embodiments described herein allow for packaging functional components (such as, for example, integrated circuit dies) of varying functionalities and dimensions (such as, for example, heights) in a same integrated circuit package. Various embodiments described herein may be integrated into a chip-on-wafer-on-substrate (CoWoS) process and a chip-on-chip-on-substrate (CoCoS) process.

Embodiments of the present disclosure relates to integrated circuit dies with rounded edges to reduce cracking in gap fill films and tip discharge, therefore, improving device performance. In some embodiments, the integrated circuit dies are formed with rounded edges.

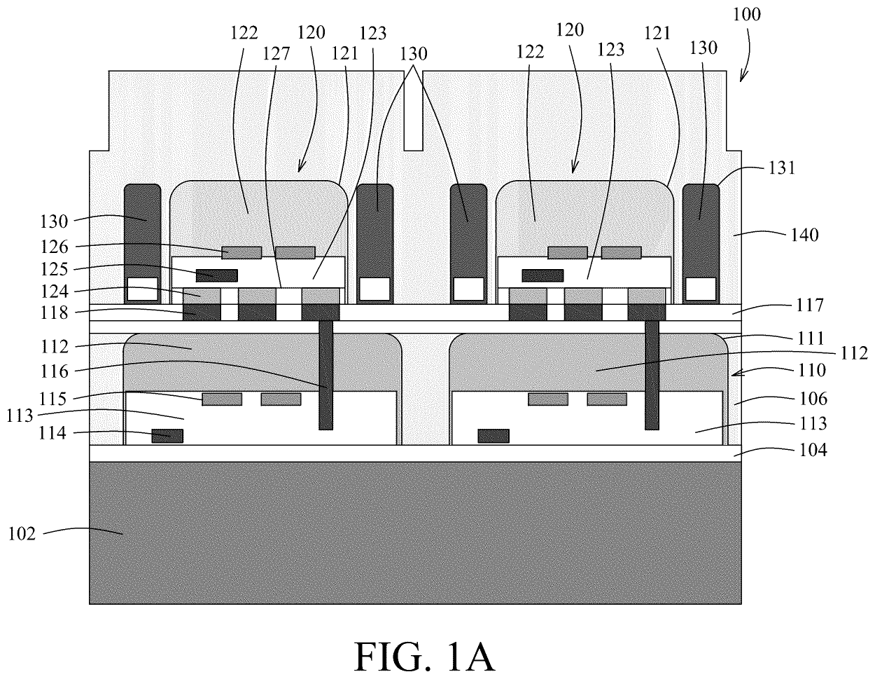

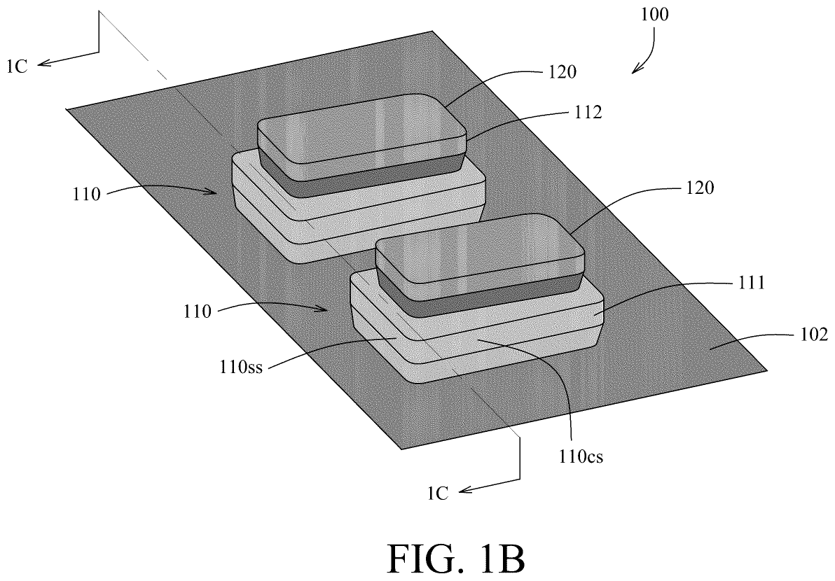

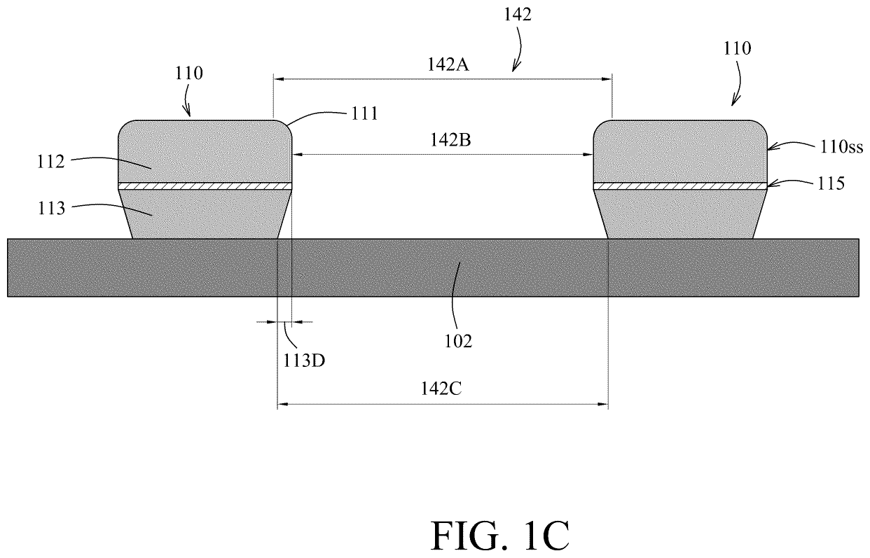

FIGS. 1A, 1B, and 1C schematically illustrate an integrated circuit (IC) package 100 according to embodiments of the present disclosure. FIG. 1A is a schematic cross-sectional view of the IC package 100. FIG. 1B is a schematic perspective views of the IC package 100 with dummy dies and gap filling material removed. The IC package 100 is a 3DIC package including two or more levels of the IC dies stacked together. In the example of FIG. 1A, the IC package 100 includes two levels of IC dies. However, more levels of IC dies may be included depending on the circuit design.

The IC package 100 includes first dies 110 bonded to a carrier substrate 102 by a bonding film 104. Each first dies 110 may include a substrate 112, a device layer 115 formed on the substrate 112, and an interconnect structure 113 formed on the device layer 115. In some embodiments, bond pads 114 is formed over the interconnect structure 113. In some embodiments, through semiconductor vias (TSVs) 116 is formed through the substrate 112. In some embodiments, a plurality of the first dies 110 may be disposed on the carrier substrate 102 in an array. A gap filling material 106 is formed in the gaps between the first dies 100.

A bonding film 117 is formed over the plurality of first dies 110. Bonding features 118 are formed in the bonding film 117. In some embodiments, the bonding features 118 may be in electric connection to the device layer 115 and/or interconnect structure 113 through the TSVs 115.

The IC package 100 further includes second dies 120 bonded to the bonding film 117. Each second die 120 may include a substrate 122, a device layer 126 formed on the substrate 122, and an interconnect structure 123 formed on the device layer 126. Conductive features 125 are formed in the interconnect structure 123. A bonding film 127 is formed over the interconnect structure 123. Bond pads 124 is formed in the bonding film 127.

The second dies 120 are stacked over the first dies 110 by bonding. The bonding film 127 of the second dies 120 is bonded to the bonding film 117 while the bond pads 124 of the second dies 120 are bonded to the bond pad 118 in the bonding film 117.

In some embodiments, the first dies 110 and the second dies 120 may be in different sizes (e.g., different heights and/or surface areas). As shown in FIG. 1A, the first dies 110 are larger than the second dies 120, and one or more dummy dies 130 may be disposed adjacent the second dies 120 to stack over the first dies 110. The dummy dies 130 are device-free dies. In some embodiments, the dummy dies 130 may include a semiconductor substrate and a bonding film. In some alternative embodiments, the first dies 110 and the second dies 120 may be in the same size, therefore, without dummy dies.

In some embodiments, a plurality of the second dies 120 and dummy dies 130 are ranged side by side in the second level. A gap filling material 140 is formed in the gaps between the second dies 130 and the second dies 120.

In some embodiments, the first dies 110 may include a logic chip. e.g., central processing unit (CPU), graphics processing unit (GPU), system-on-a-chip (SoC), application processor (AP), microcontroller, etc.), an application-specific integrated circuit (ASIC) chip, an analog chip, a sensor chip, a wireless application chip (e.g., a Bluetooth chip, a radio frequency chip, etc.), or a voltage regulator chip. In some embodiments, the second dies 120 may be a memory chip, such as a high bandwidth memory chip, a dynamic random access memory (DRAM) chip or a static random access memory (SRAM) chip.

According to embodiments of the present disclosure, one or more of the first dies 110, the second dies 120, and the dummy dies 130 include rounded corners. For example, as shown in FIG. 1A, each of the first dies 110 has substantially rectangular die area with rounded corners 110cs. Particularly, the first die 110 includes planar side surface 110ss connected by rounded corners 110cs. The rounded corners 110cs may be defined by curved side surfaces.

In some embodiments, as shown in FIG. 1A, one or more of the first dies 110, the second dies 120, and the dummy dies 130 include rounded top edges 111, 121, 131 respectfully. The rounded top edge 111 connects planar top surfaces to the side surfaces, such as side surfaces 110ss.

FIG. 1C is a schematic partial cross sectional view of the IC package 100 along the 1C-1C line in FIG. 1B. As shown in FIG. 1C, a trench 142 is formed between two neighboring dies 110. The trench 142 may have varied width due to the shape of the dies 110. For example, the trench 142 has a width 142A near the opening or the rounded top edge 111, a width 142B between side surfaces 110ss in the middle section, and a width 142C near the bottom. The dies 110 are positioned with the substrate 112 facing up and the dielectric layer, such as passivation layers and interconnect layers, facing down. It has been observed that, after the dies 110 are diced, the dielectric layer may shrink at a greater degree than the substrate 112. As shown in FIG. 1C, the dielectric layer may shrink for about 1% of the length. For example, the dielectric layer may have a shrinkage 113d in a range between about 0.5 micron and about 2 microns. As a result of the shrinkage, the width 142C at the bottom is greater than the width 142B. Because of the rounded top edge and the width 142A is greater than the width 142B. In some embodiments, the width 142B is in arrange between about 50 microns and about 550 microns.

The rounded corners and rounded top edges in the dies prevent tip charges. The rounded corners and edges also facilitate filling of high aspect ratio trenches between the dies, thus, reducing overall size of the IC packaging.

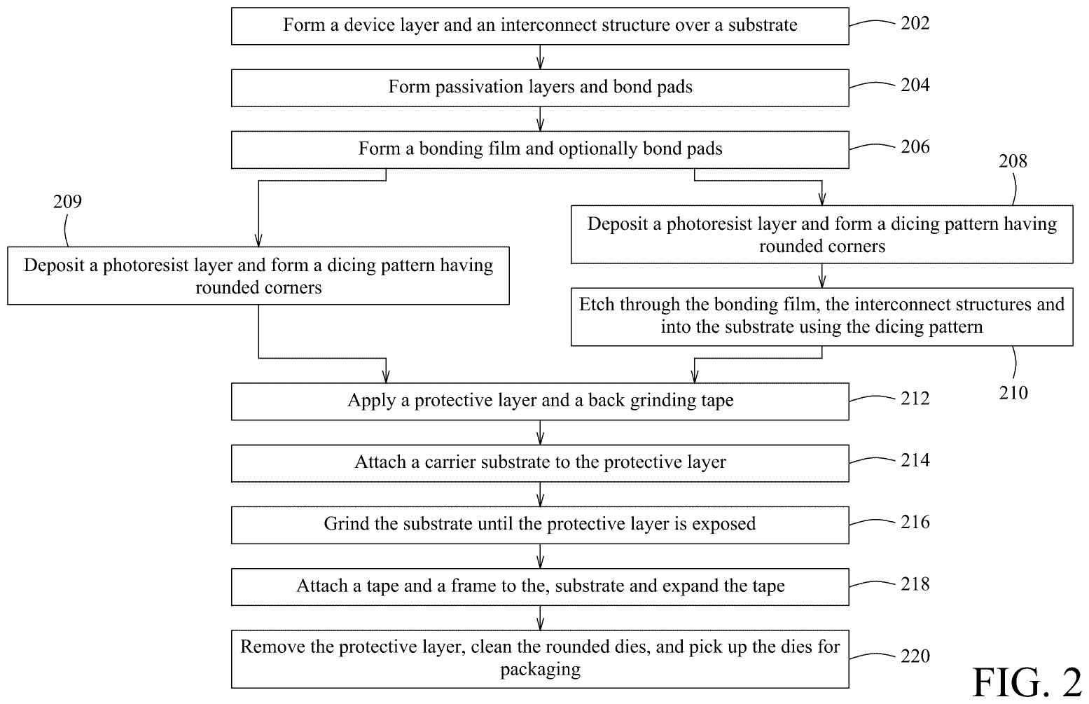

FIG. 2 is a flow diagram of a method 200 of forming of integrated dies with rounded corners according to embodiments of the present disclosure. By combining various steps, the method 200 may be used to fabricate integrated circuit dies or dummy dies with rounded corners. Particularly, the method 200 forms IC dies with rounded corners used in 3DIC packaging with reduced cracking.

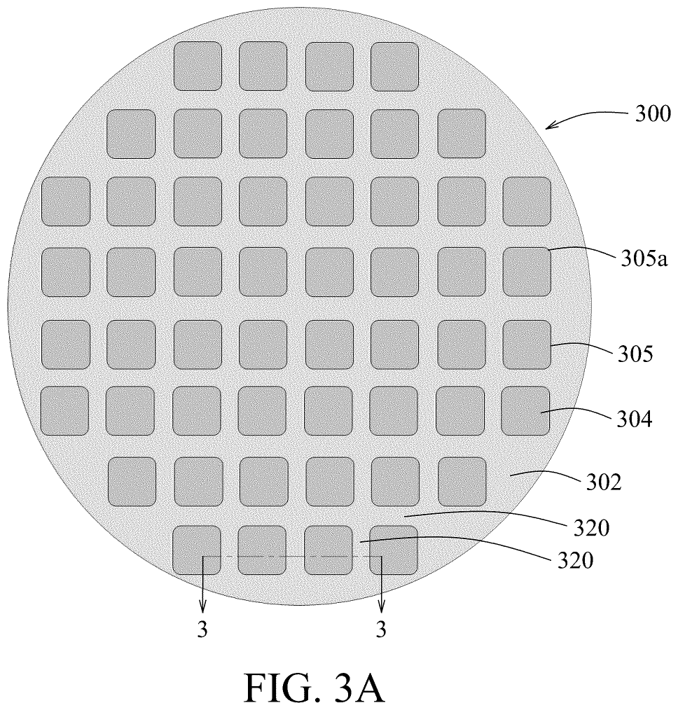

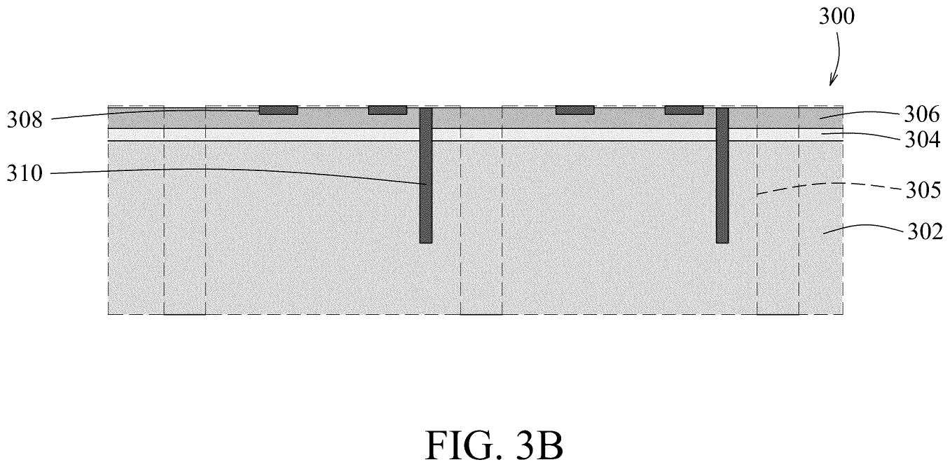

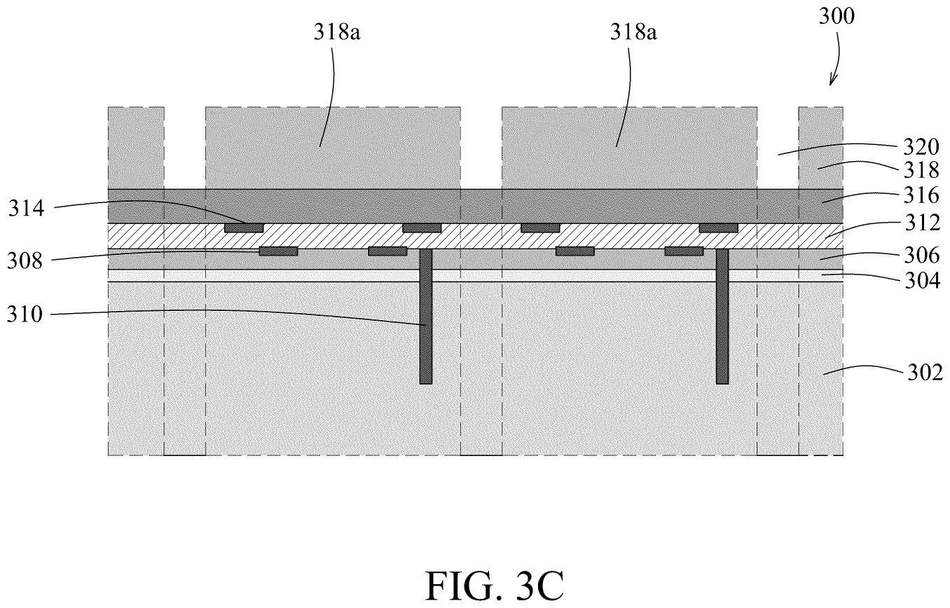

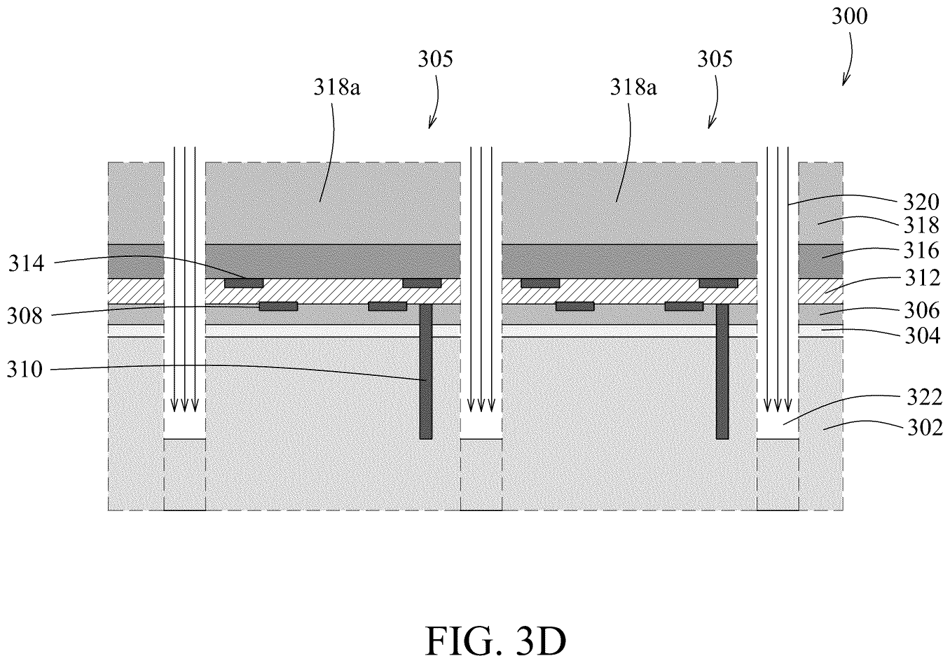

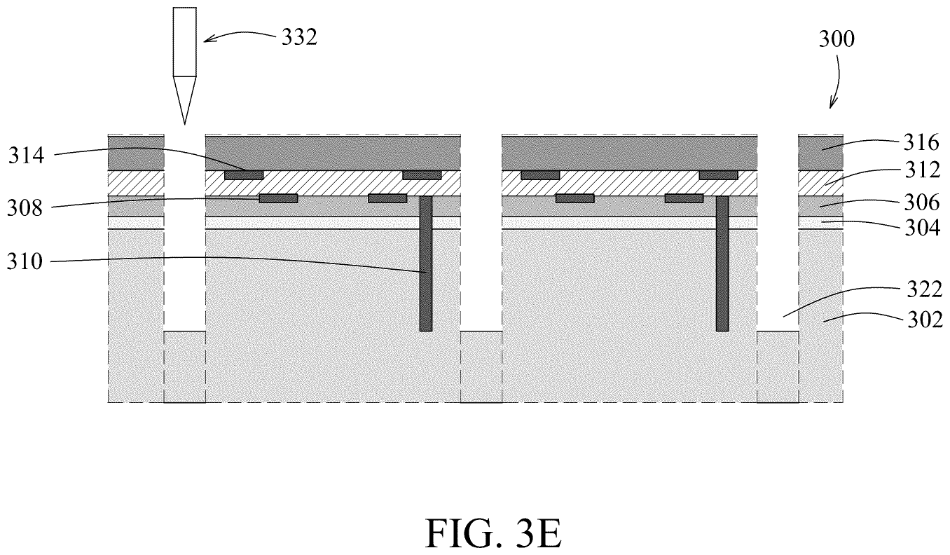

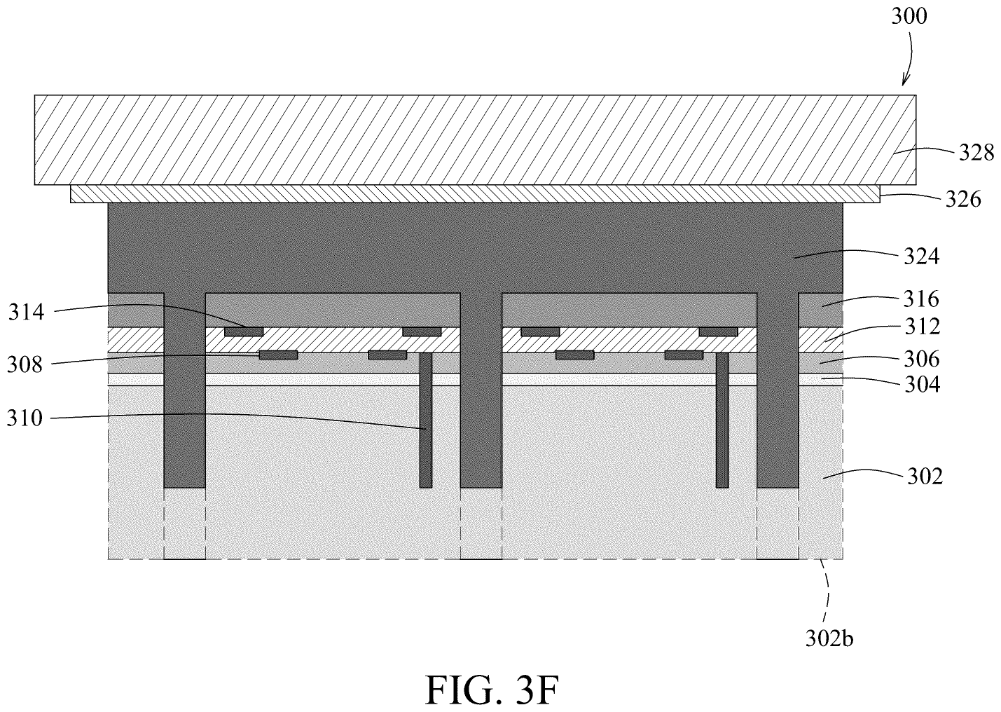

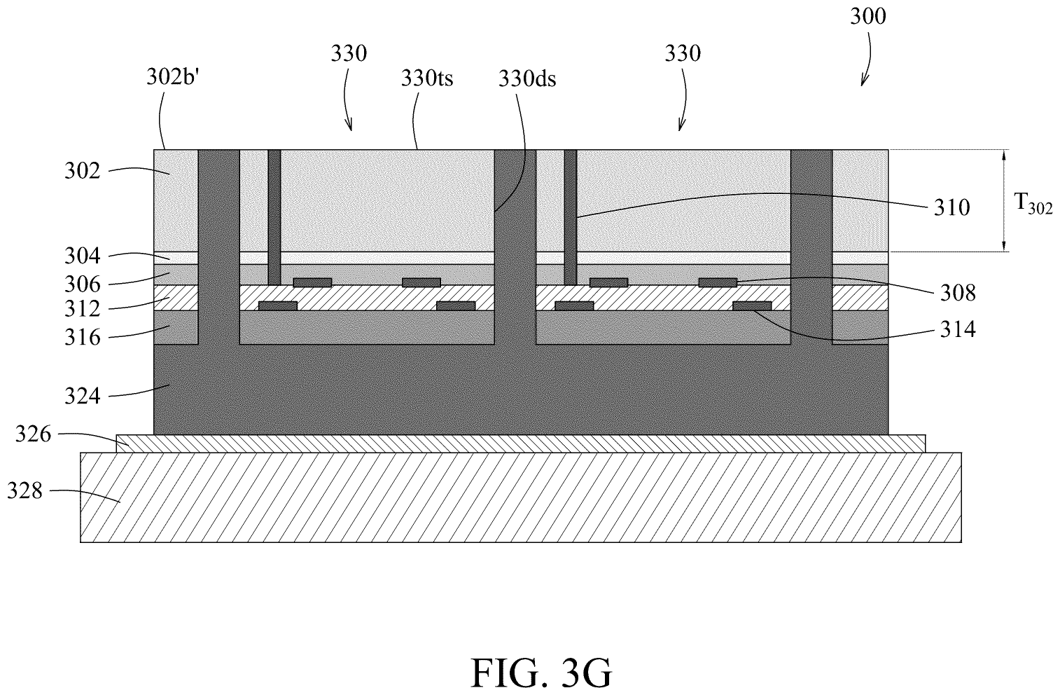

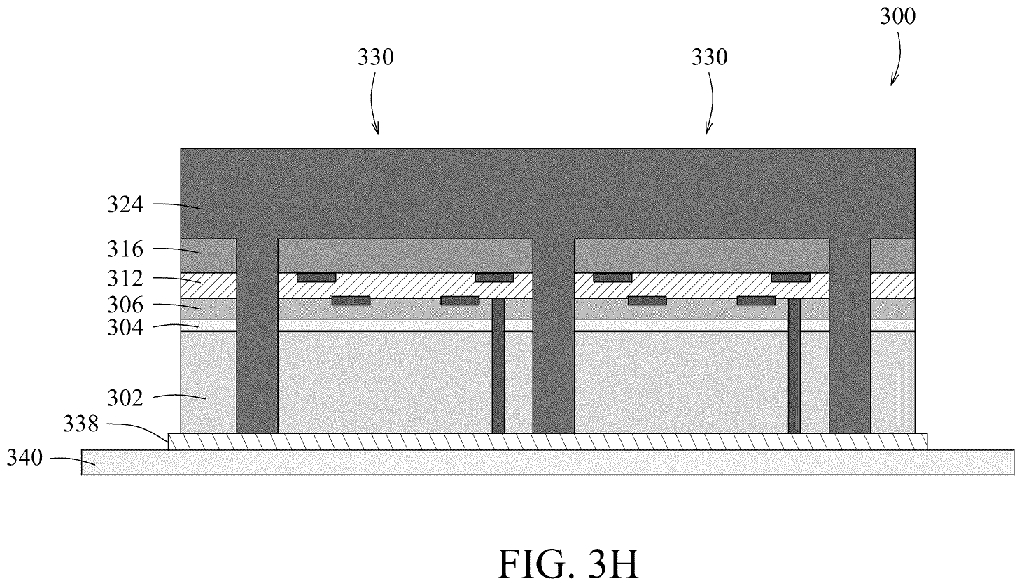

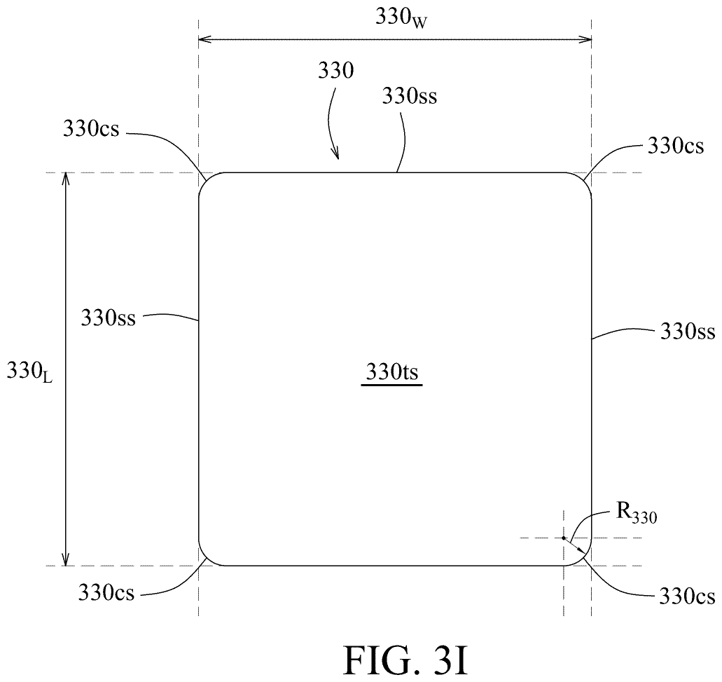

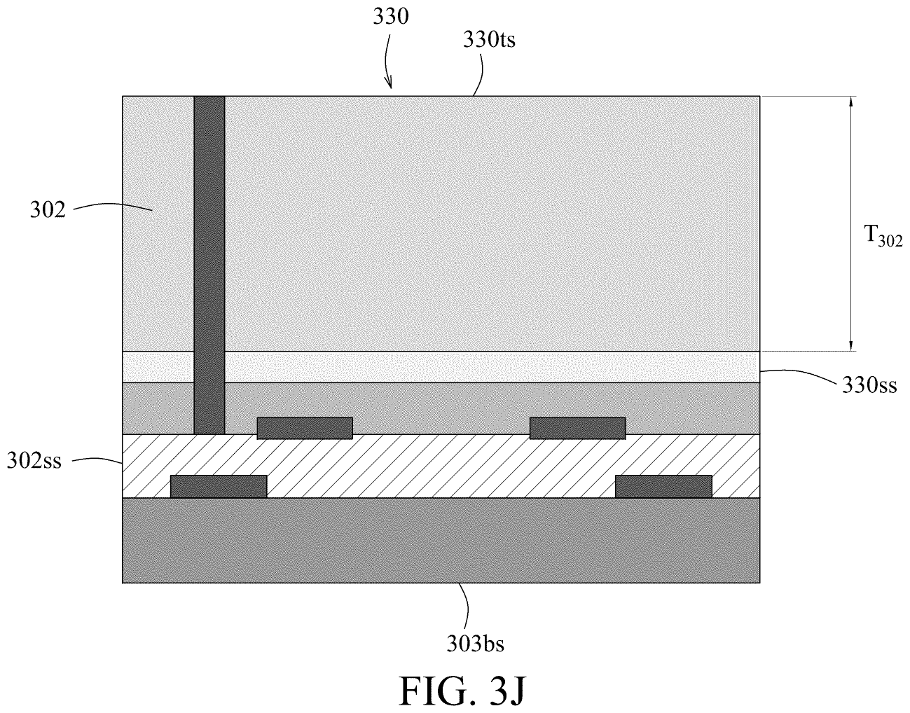

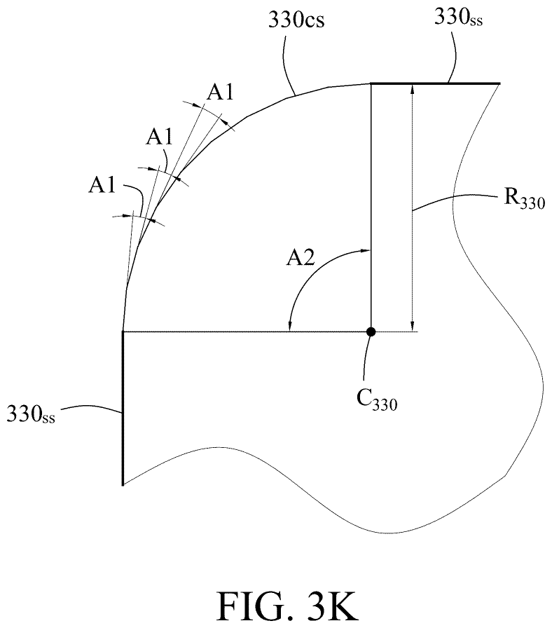

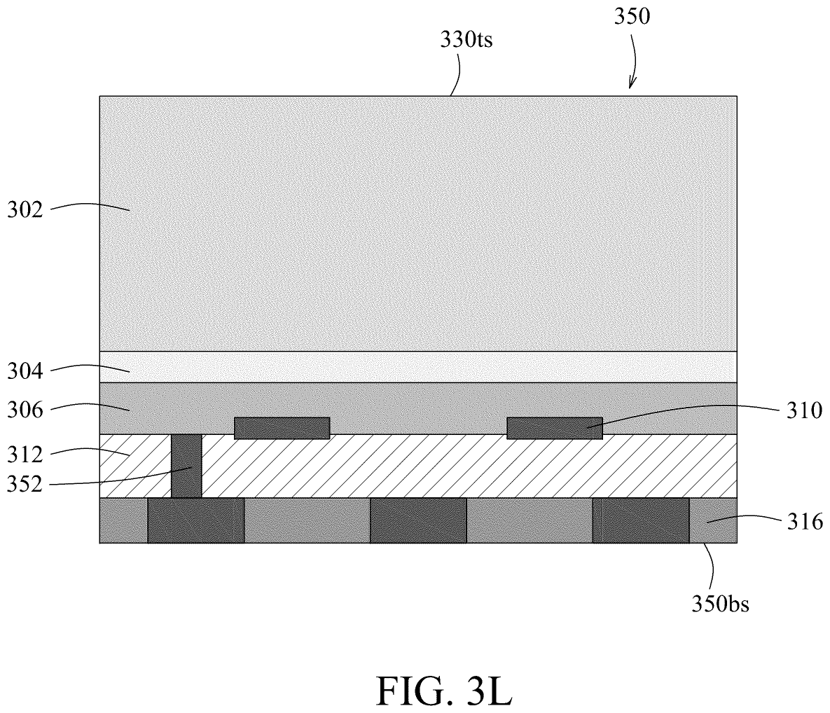

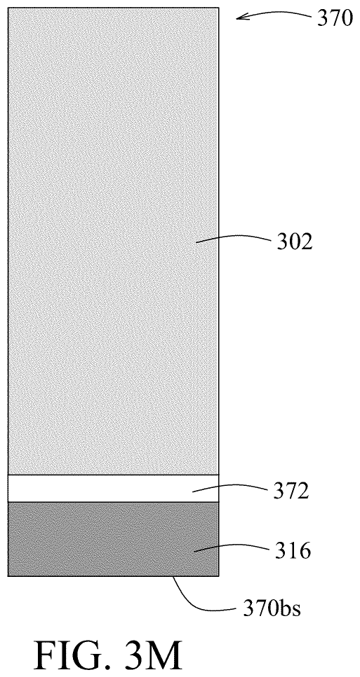

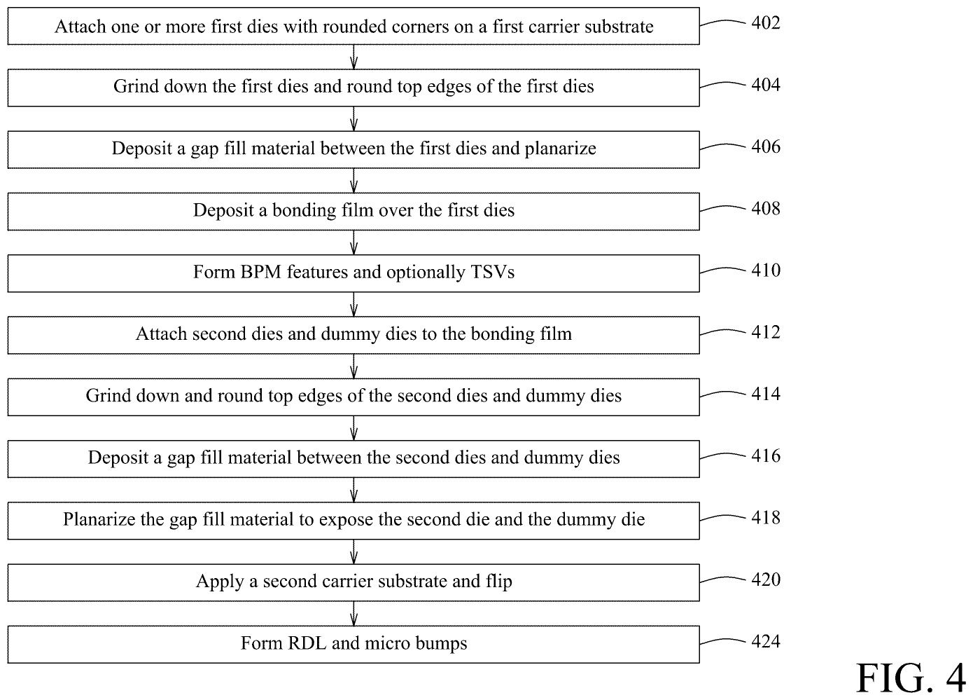

FIGS. 3A-3K schematically demonstrate various processing stages during fabrication of integrated circuit dies according to embodiments of the present disclosure.

In operation 202, a device layer 304 is formed over a semiconductor substrate 302, and an interconnect structure 306 formed over the device layer 304, as shown in FIGS. 3A and 3B. FIG. 3A is a schematic top view of a device structure 300 with a plurality of die areas 305 formed thereon. FIG. 3B is a schematic partial cross-sectional view of the device structure 300 after operation 202.

The semiconductor substrate 302 is formed from one or more semiconductor materials. In some embodiments, the semiconductor substrate 302 is a bare substrate including an elementary semiconductor, such as silicon or germanium in a crystalline, a polycrystalline, or an amorphous structure; a compound semiconductor such as silicon carbide, gallium arsenide, gallium phosphide, indium phosphide, indium arsenide, and/or indium antimonide; an alloy semiconductor, such as e.g., silicon-germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), etc. ; combinations thereof, or other suitable material. In some embodiments, the semiconductor substrate 302 may include one or more dopants. The semiconductor substrate 302 may also be in the form of silicon-on-insulator (SOI). The SOI substrate may comprise a layer of a semiconductor material, e.g., silicon, germanium and/or the like, formed over an insulator layer, e.g., buried oxide and/or the like, which is formed on a silicon substrate. In addition, other substrates that may be used include multi-layered substrates, gradient substrates, hybrid orientation substrates, any combinations thereof and/or the like.

The device layer 304 is formed on a front side of the semiconductor substrate 302. The device layer 304 include a variety of devices, such as transistors, capacitors, resistors, inductors and the like, which may be used to generate the desired structural and functional requirements of the design for the integrated circuit in each die area 305.

The interconnect structure 306 is formed over the device layer 304. The interconnect structure 306 may include multiplayers of dielectric materials having conductive features 308 formed therein. The conductive features 308 embedded in the interconnect structure 306 are designed to connect the various devices in the device layer 304 to form functional circuitry. The interconnect structure 306 is formed of alternating layers of dielectric and conductive material and may be formed through any suitable processes, such as deposition, damascene, dual damascene, etc. In some embodiments, other conductive features, such as through semiconductor vias (TSVs) 310 may be formed through the interconnect structure 306, the device layer 304, and the semiconductor substrate 302.

As shown in FIG. 3A, the device layer 304 and the interconnect structure 306 include structures formed in a plurality of die areas 305 to form a plurality of dies. In some embodiments, each of the die area 305 include rounded corners 305a. The device layer 304 and the interconnect structures 306 are formed by layer by layer using various semiconductor processes, such as photolithography, patterning, etching, deposition, cleaning, annealing, planarization, etc.

Masks are used in various layers of fabrications of various layers. For example, one or more device masks are used in fabrication of the device layer 304. In some embodiments, the one or more device masks include patterning features arranged in rectangular areas with rounded corners, corresponding to the die areas 305. One or more interconnect masks are used to fabricate the interconnect structure 306. In some embodiments, the one or more interconnect masks include patterning features arranged in rectangular areas with rounded corners, corresponding to the die areas 305. In some embodiments, seal rings are formed along a perimeter of the die area 305. In some embodiments, the seal rings may include rounded corners.

In operation 204, a passivation layer 312 may be formed over the interconnect structure 306, as shown in FIG. 3C. FIG. 3C is a partial cross-sectional view of the device structure 300. The passivation layer 312 may include one or more dielectric material layers having conductive features 314 formed therein. The conductive features 314 may include contact pads formed on a top surface of the passivation layer 312 as contact terminals. In some embodiments, the conductive features 314 provide electrically connections to the devices in the device layer 304 via the interconnect structure 306. In some embodiments, the conductive features 314 are distributed within an area corresponding to the die area 305, which is in a rectangle shape with rounded corners from the top view. One or more masks are used to form the conductor features 314 in the passivation layer 312. In some embodiments, the one or more masks including patterning features arranged in rectangular areas with rounded corners, corresponding to the die areas 305.

In operation 206, a bonding film 316 is deposited over the adjustment layer 206, as shown in FIG. 3C. The bonding film 316 is configured to bond the dies to be formed with other dies during subsequent packaging. Particularly, the bonding film 316 may be selected from any material suitable to bond the die with another die or with another bonding filming.

The bonding film 316 may be formed with any suitable material for bonding in packaging. In some embodiments, the bonding film 316 may be made of silicon oxide (SiOₓ, where x>0), silicon oxynitride (SiOₓN_{y}, where x>0 and y>0), silicon nitride (SiNₓ, where x>0), or other suitable dielectric material. In some embodiments, the bonding film 316 may be formed by suitable fabrication techniques such as CVD, HDPCVD or PECVD. In some embodiments, the bonding pads may be formed by suitable fabrication techniques such as electroplating or deposition. In some embodiments, the bonding film 316 has a thickness in a range between about 100 Å and about 1000 Å. The thickness of the bonding film 316 may be selected according to the queue time. Because the bonding film 316 may absorb moisture during wait time, it is desirable to have a thinner bonding film 316 to avoid trapping excess moisture in IC packages if there is long queue time for the dies during packaging.

In some embodiments, bond pads may be formed in the bonding film 316 to provide electrical connection with another die. In some embodiments, the bonding pads may be made of copper or other suitable metal that is easy for forming hybrid bonding. A bond pad mask is used to form the bond pads. In some embodiments, the bond pad mask including patterning features arranged in rectangular areas with rounded corners, corresponding to the die areas 305.

In operation 208, a photoresist layer 318 is deposited over the bonding film 316 and a dicing pattern is formed in the photoresist layer 318, as shown in FIG. 3C. A photolithography process is followed to form a dicing pattern including photoresist pads 318a defined by trenches 320 in the photoresist layer 318. The photoresist layer 318 is selectively removed to form the trenches 320. As shown in FIG. 3C, the bonding film 316 is exposed at the bottoms of the trenches 320. The trenches 320 may form a grid defining a plurality of die areas 305, as shown in FIG. 3A. The photoresist pads 318a cover the die areas 305 in the underlying layers. In some embodiments, the photoresist pad 318a are rectangular areas with rounded corners, corresponding to the die areas 305.

In operation 210, a plasma dicing process is performed to separate the die areas 305, as shown in FIG. 3D. FIG. 3D is a partial cross-sectional view of the device structure 300 after operation 210. In some embodiments, one or more plasma etch processes are performed to etch through the bonding film 316, the passivation layer 312, the device layer 304, and into the semiconductor substrate 302 forming dicing trenches 322, as shown in FIG. 3D. The patterned photoresist layer 318 is used as a mask to form the dicing trenches 322.

In some embodiments, a continuous plasma process may be performed to etch the bonding film 316, the passivation layer 312, the device layer 304, and at partially through the semiconductor substrate 302. Process gasses and conditions can be adjusted based on the materials to be removed. In some embodiments, one or more etching chemistries in the plasma dicing operation to remove various layers.

In some embodiments, when material to be etched including silicon oxide, a process gas for plasma dicing may include C₄F₆ or a fluorine-based gas, at a temperature of less than 200° C. (e.g., less than 150° C.), an RF power of greater than 50 W (e.g., greater than 100 W), and at a pressure of less than 3 torr (e.g., less than 200 mtorr). When the material to be etched including a SiOC, a process gas for plasma dicing may include N₂ and H₂, or SO₂ and O₂, at a temperature of less than 200° C. (e.g., 20-100° C.), an RF power of greater than 100 W (e.g., greater than 300 W), and at a pressure of less than 3 torr (e.g., less than 200 mtorr). In some embodiments, the Bosch Process may be used to dice into the semiconductor substrate 302. The bosch process is consisted of the cyclic isotropic etching and fluorocarbon-based protection film deposition by quick gas switching. The SF₆ plasma cycle etches silicon, and the C₄F₈ plasma cycle creates a protection layer.

The dicing trenches 322 may form a grid in the bonding film 316, the passivation layer 312, the device layer 304, and into the semiconductor substrate 302 forming the plurality of die areas 305. The dicing trenches 322 are formed into the semiconductor substrate 302 but not through the semiconductor substrate 302 so that the die areas 305 remain connected by the semiconductor substrate 302. Etching rate of the plasma etching process for plasma dicing may be selected depend on the thickness of the substrate 302. In some embodiments, the plasma dicing rate for a silicon substrate may in greater than 20 micron per minute. The dicing trenches 322 are deep enough so that the die areas 305 may be separated from one another when the semiconductor substrate 302 is grinded down from the back side. In some embodiments, the dicing trenches 322 have a width in a range between about 6 microns and about 10 microns. The die areas 305 include rounded corners 305a in a top view. After the plasma dicing operation, the photoresist layer 318 may be removed for subsequent processing.

Other dicing methods may be performed in place of forming a dicing pattern with rounded corners in operation 208 followed by a plasma dicing process in operation 210. In some embodiments, a laser dicing may be performed. For example, Operation 209 may be performed after operation 206 in place of the operations 208, 210.

In operation 209, a laser dicing may be performed to form the dicing trenches 322, as shown in FIG. 3E. FIG. 3E is a partial cross-sectional view of the device structure 300. A laser source 332 may be used to cut the dicing trenches 322 by following a cutting path defining die areas 305 with rounded corners. In some embodiments, the laser dicing may be performed at about 300 mm/s.

In operation 212, a protective layer 324 is deposited to fill the dicing trenches 322 and cover the die areas 305, as shown in FIG. 3F. FIG. 3F is a partial cross-sectional view of the device structure 300. The protective layer 324 is used to cover and protect the bonding film 316 and exposed portions of the semiconductor substrate 302, the device layer 304 and the interconnect structure 306 during subsequent processing. The protective layer 324 may be formed by any material that is capable of isolate the die areas 305 from the processing environment during the subsequent processing. The protective layer 324 may also be easily removed from the die areas 305. In some embodiments, the protective layer 324 may be formed from a photoresist material. In some embodiments, the protective layer 324 may be deposited over the die areas 305 by a spin-on coating process followed by a curing process, e.g., a low temperature curing technique. However, any suitable coatings, any suitable deposition techniques, and any suitable curing techniques may also be used. Alternatively, the protective layer 324 may be a curable resin, polyimide coating, polybenzoxazole (PBO), epoxy films, or the like.

In operation 214, a back grinding tape 326 and a carrier wafer 328 are attached to the protective layer 324, as shown in FIG. 3F. The back grinding tape 326 is first attached to the protective layer 324. The carrier wafer 328 is then attached to the back grinding tape 326 so that the semiconductor substrate 302 may be thinned down from a back side 302b.

In operation 216, the semiconductor substrate 302 is flipped over and a back grinding process is performed to thin down the semiconductor substrate 302 from the back side 302b, as shown in FIG. 3G. FIG. 3G is a partial cross-sectional view of the device structure 300 after operation 218. The back grinding process reduces thickness of the semiconductor substrate 302 to a target thickness according to the design.

In some embodiments, the back grinding process is performed to reduce the thickness of the semiconductor substrate 302 and to “dice” the device structure 300 into a plurality of dies 330. As shown in FIG. 3G, the back grinding process removes the portion of the semiconductor substrate 302 without the dicing trenches 322 and exposes the protective layer 324. In some embodiments, the concentration of the protective layer 324 in the grinding waste may be used as an end point for the back grinding process. After the back grinding process, the thickness of the semiconductor substrate 302 is reduced to a thickness T₃₀₂. In some embodiment, the thickness T₃₀₂ is in a range between about 50 microns and about 100 microns.

Because of the masks with rounded corners are used during the operations, the dies 330 does not have sharp corners between side surfaces 330ss. However, sharp corners still exist between a top surface 330ts and side surfaces 330ss.

Even though the dies 330 are diced apart from one another after the operation 214, the plurality of dies 330 remain glued together by the protective layer 324. The dies 330 are separated by the dicing trenches 322 which are filled with the protective layer 324. The bonding film 316 on each die 330 is in contact with the protective layer 324, which is attached to the back grinding tape 326.

In operation 218, one or more expanding processes are performed to increase the distance between the dies 330, as shown in FIG. 3H. After the back grinding process, the plurality of dies 330 are flipped over and attached to an expansion tape 338 on a frame 340. As shown in FIG. 3H, the plurality of dies 330 are glued to the expansion tape 338 at the back side 202b. The carrier wafer 328 and the back grinding tape 326 are then removed. The expansion tape 338 is then stretched so that the dicing trenches 322 between the dies 330 widens.

In some embodiments, the expansion tape 338 may be relaxed, for example by applying ultra-violet radiation, and stretched to increase the distance between neighboring dies 330. The dies 330 are then individually picked up from the expansion tape 338 for subsequent packaging. In some embodiments, one or more additional expansion processes may be performed to further increase the distance between neighboring dies 330 for ease of handling.

In operation 220, the dies 330 are cleaned and ready for subsequent packaging, as shown in FIGS. 3I and 3J. FIG. 3I is a partial cross-sectional view of an individual 330 after operation 120. FIG. 3J is a schematic top view of an individual die 330. The dies 330 are cleaned to remove the protective layer 324 by a suitable process, for example, by an ashing process when the protective layer 324 includes photoresist material. After cleaning, the bonding film 316 on each the dies 3304 is exposed.

The individual die 330 according to the present disclosure includes various rounded corners. In some embodiments, the die 330 formed above may be used on a bottom layer of a 3DIC package with the top surface 330ts facing a top layer of dies. As shown from the top view in FIG. 3J, the die 330 has a substantially rectangular die area having a width 330W and a length 330L. In some embodiments, the width 330w is in a range between about 3 mm to about 7 mm. The length 330L is in a range between about 3 mm to about 12 mm. The die area is defined by four planar side surfaces 330ss connected by four curved side surfaces 330cs.

FIG. 3K is a schematic enlarged view of the die 330 showing the profile of the curved side surface 330cs. In some embodiments, particularly when the die 330 is diced by laser dicing, the curved side surface 330cs may be formed by a plurality of straight sections at small angular steps A1 from one another. In some embodiments, the angular steps A is in a range between about 0° and about 5°. The curved side surfaces 330cs may have a radius of curvature R₃₃₀ in a range between about 0.3 microns and about 1.5 microns. The curved side surface 330cs may form an angle A2 from a center of curvature C₃₃₀. In some embodiments, the angle A2 is in a range between about 90° and about 135°.

It should be noted that the die 330 may be in other shapes, for example in a substantially polygonal shape defined by multiple planar side surfaces connected by curved side surfaces.

As discussed above, the dies 330 may be packaged in a bottom layer of a 3DIC. The method 200 may be modified, for example by modifying or omitting various operations, to fabricate dies with rounded dies to be packaged in a top layer of a 3DIC. In some embodiments, the method 200 may be used to fabricate dummy dies with rounded corners.

FIG. 3L is a schematic view of a die 350 according to embodiments of the present disclosure. The die 350 may be used in a top layer of a 3DIC. The die 350 is similar to the die 330 except that the die 350 includes bond pad features 354 in the bonding film 316. The die 350 includes a top surface 350ts and a bottom surface 350bs. The top surface 350ts is formed of the semiconductor substrate 302. The bottom surface 350bs includes the bonding film 316. The bond pad features 354 are formed in the bonding film 316 and exposed to a bottom surface 350bs. The bond pad features 354 may be connected via conductors 252 in the passivation layer 312 to the devices in the device layer 304. The die 350 may be fabricated and diced using the method 200 above. The bond pad features 354 may be formed in operation 206. Similar to the die 330, the die 350 includes rounded corners.

FIG. 3M is a schematic view of a dummy die 370 according to embodiments of the present disclosure. The dummy die 370 may be used in one or more layers of a 3DIC. Similar to the dies 330, 350, the dummy die 370 includes rounded corners connecting between side surfaces. The dummy die 370 includes a top surface 370ts and a bottom surface 370bs. The top surface 370ts is formed of the semiconductor substrate 302. The bottom surface 370bs includes the bonding film 316. The bond pad features 354 may be formed in operation 206. Similar to the dies 330, 350, the dummy die 370 includes rounded corners connecting between side surfaces. The dummy die 370 may include an adhesive layer 372 formed between the semiconductor substrate 302 and the bonding film 316. The adhesive layer 372 may comprise silicon oxide. In some embodiments, the adhesive layer 372 is formed of USG (undoped silica glass). In some embodiments, the adhesive layer 372 has a thickness in a range between about 100 Å and about 1000 Å. In some embodiments, the dummy die 370 may be fabricated and diced using the method 200 above. For example, the dummy die 370 may be fabricated using the method 200 with operations 202 and 204 omitted.

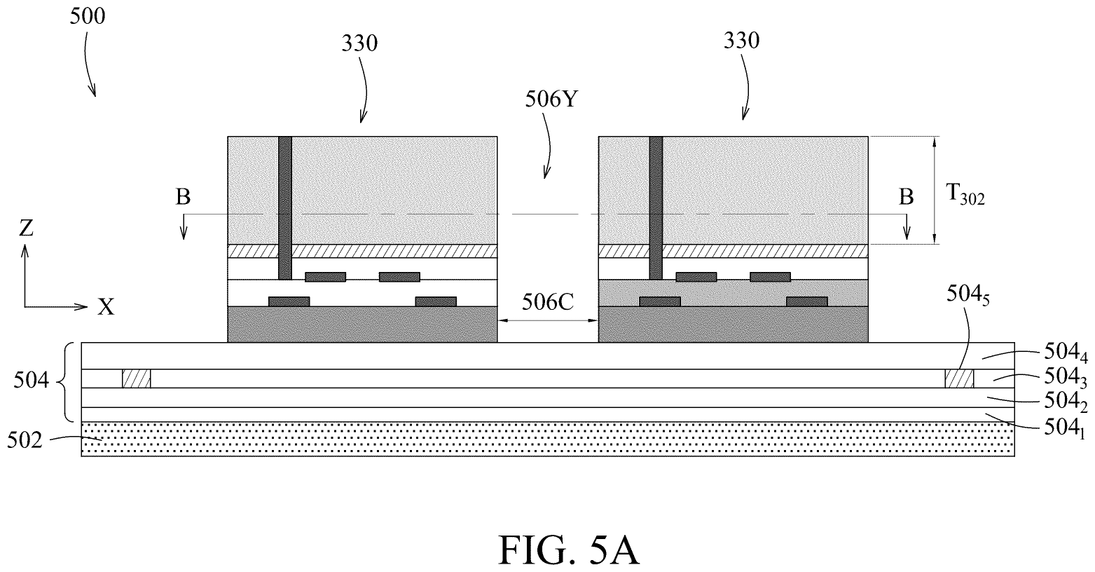

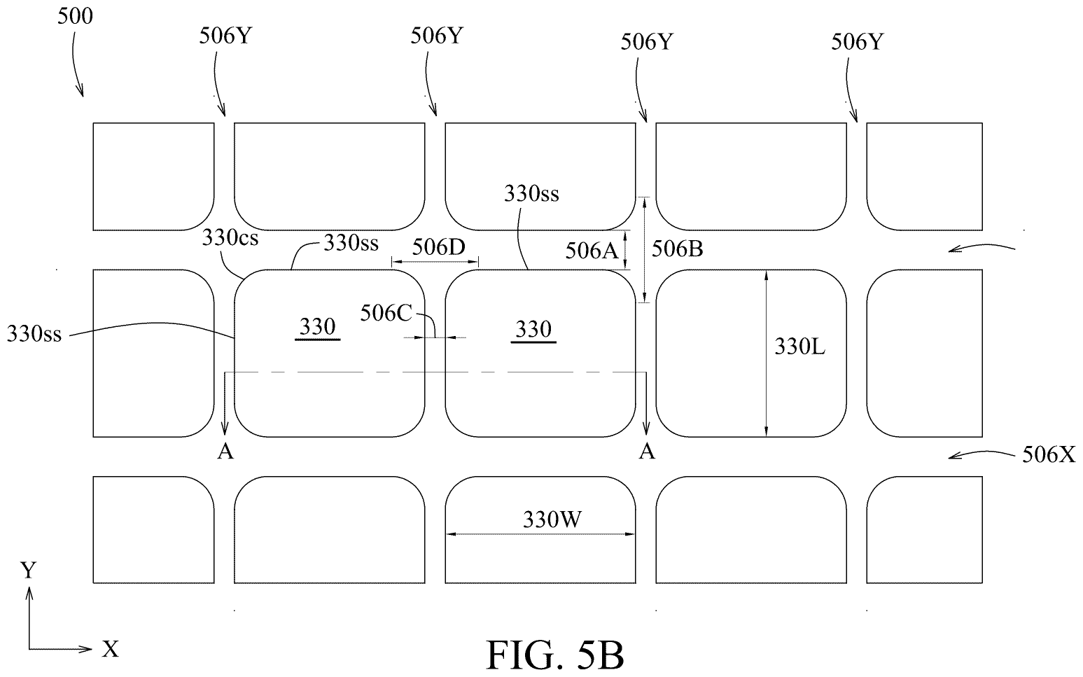

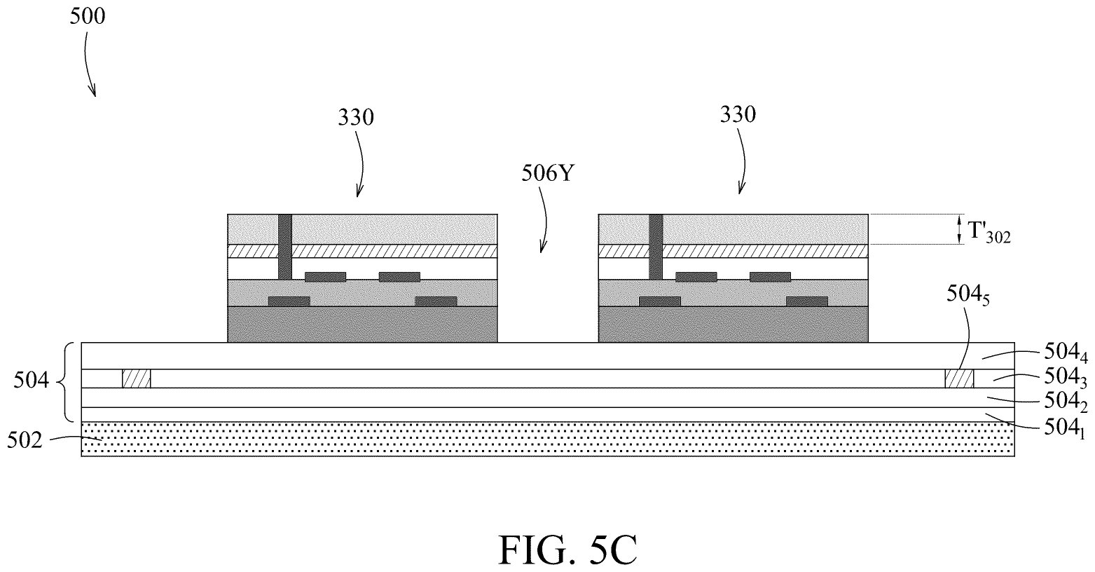

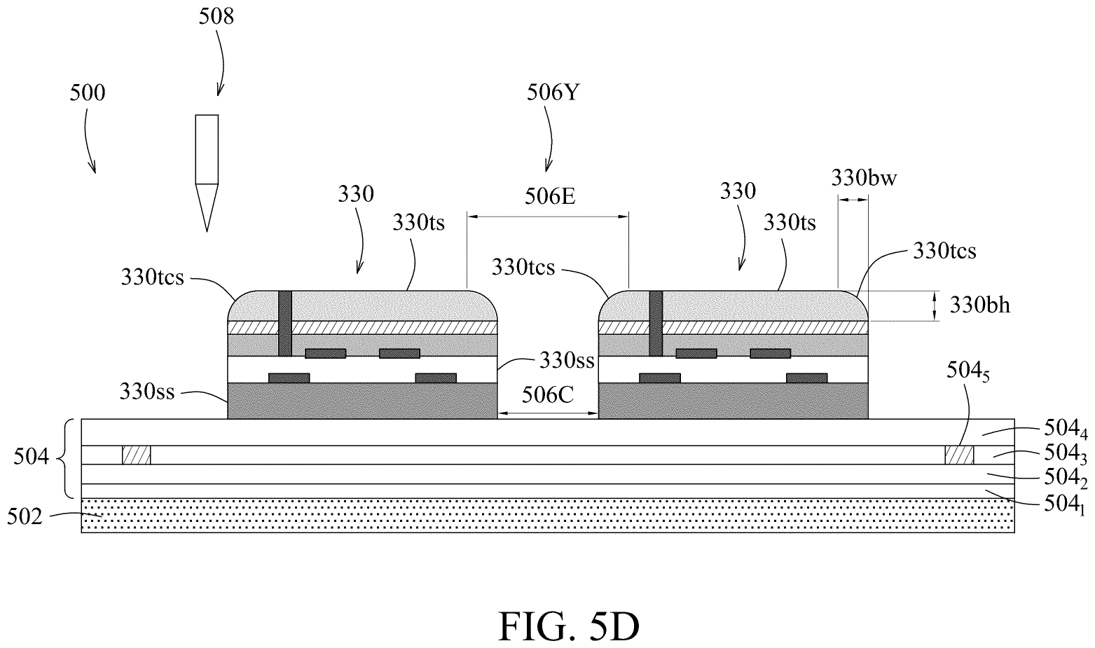

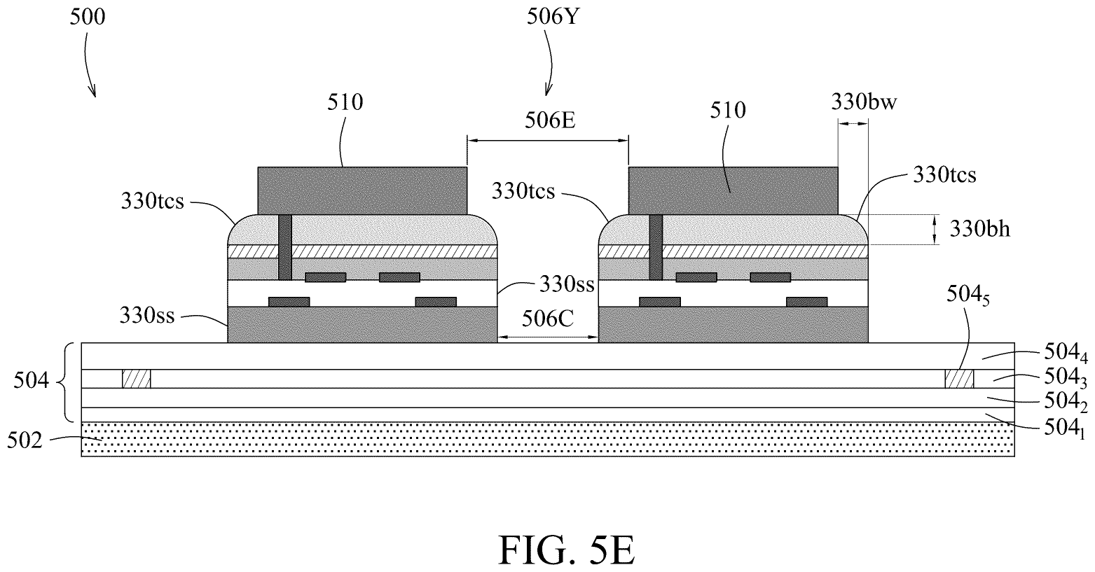

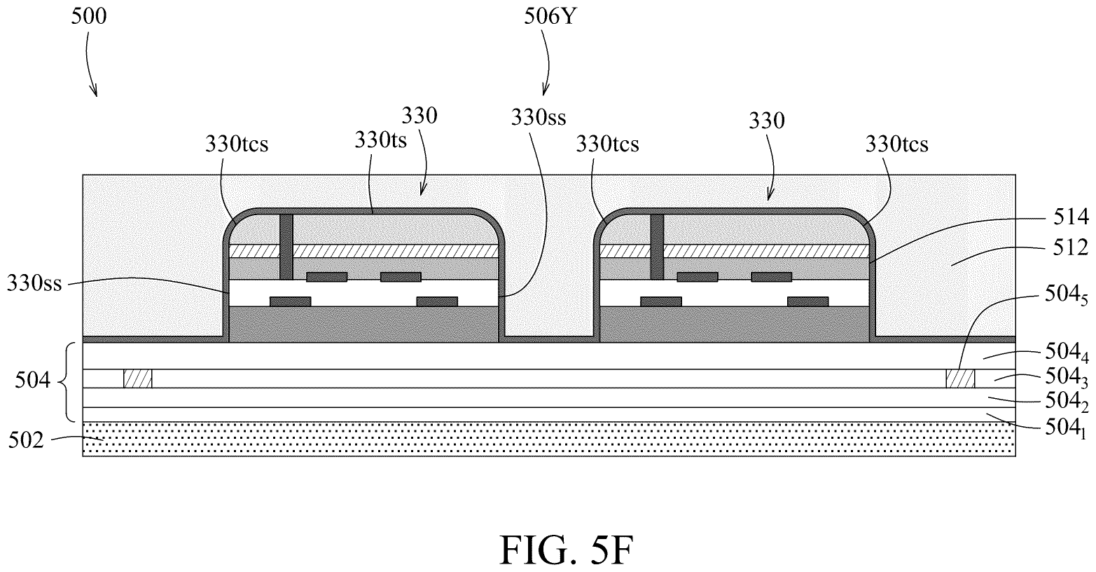

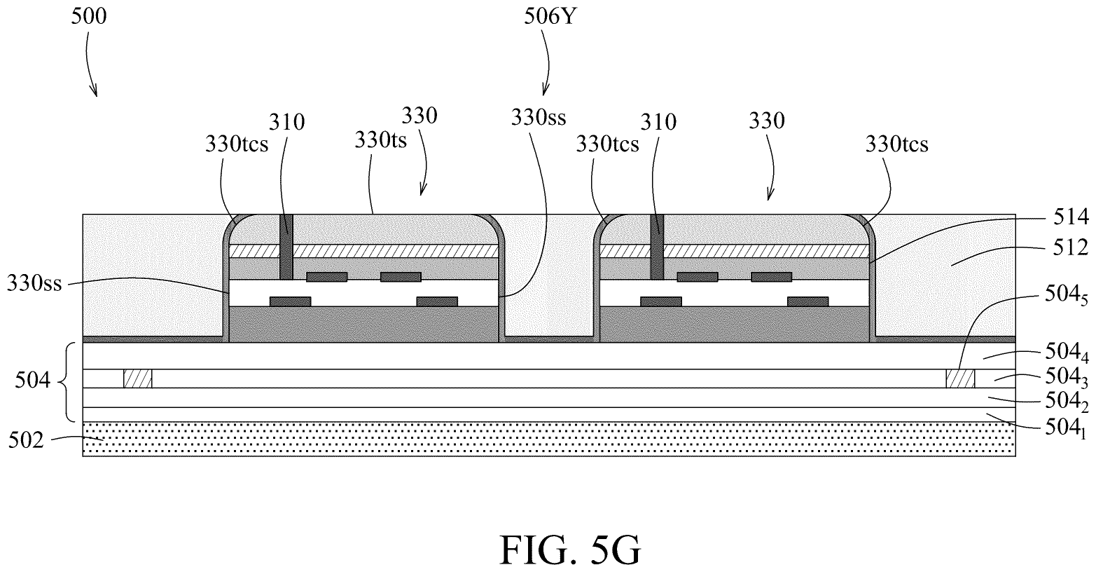

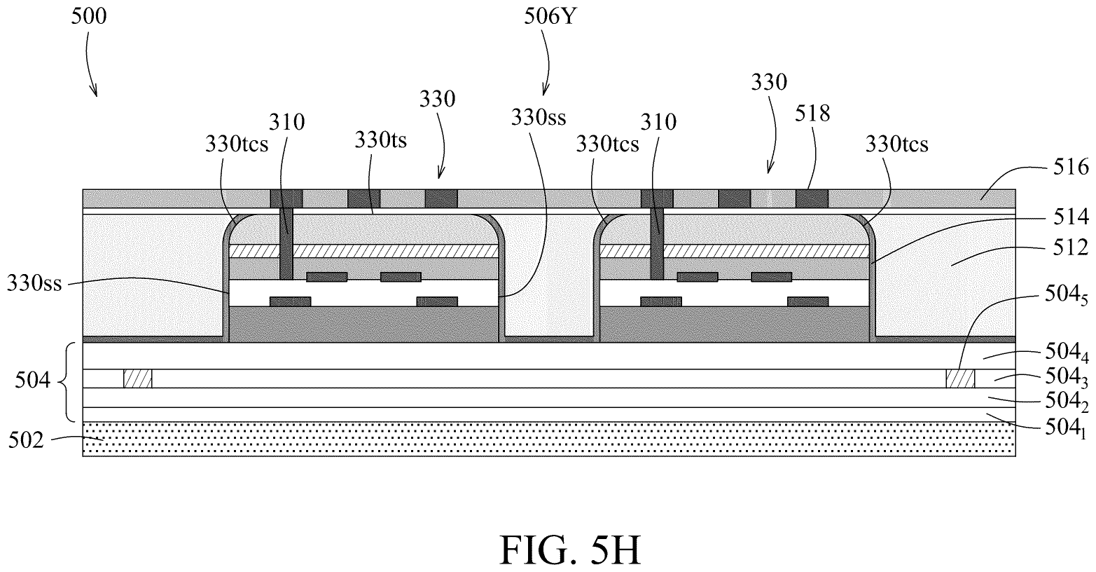

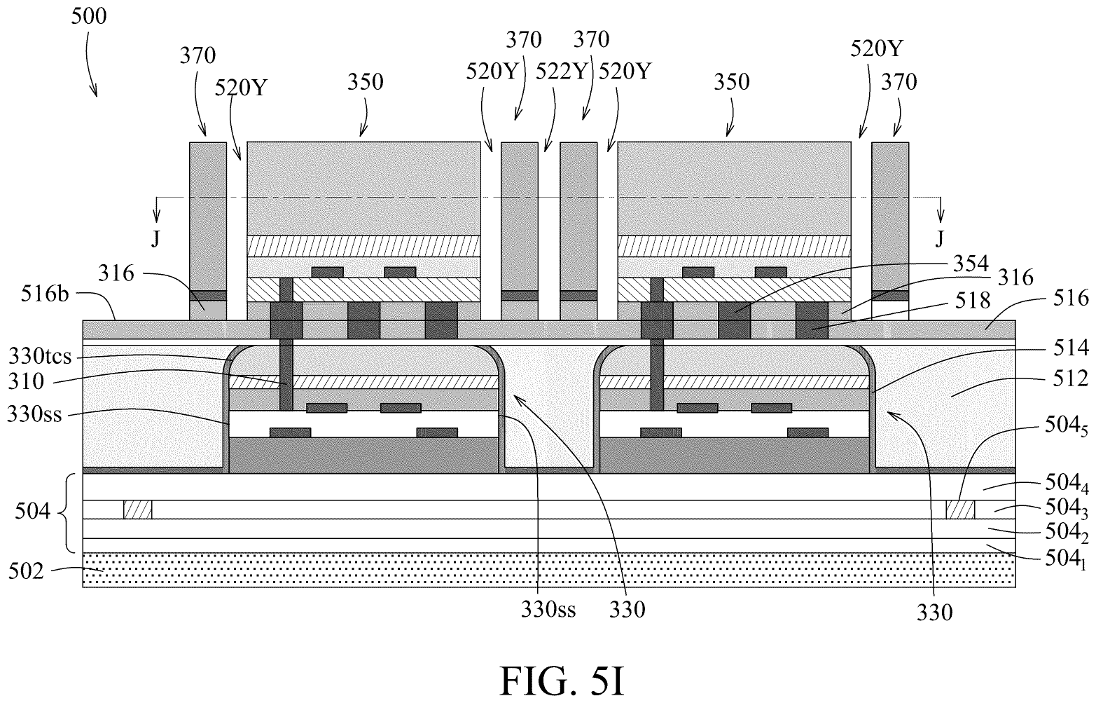

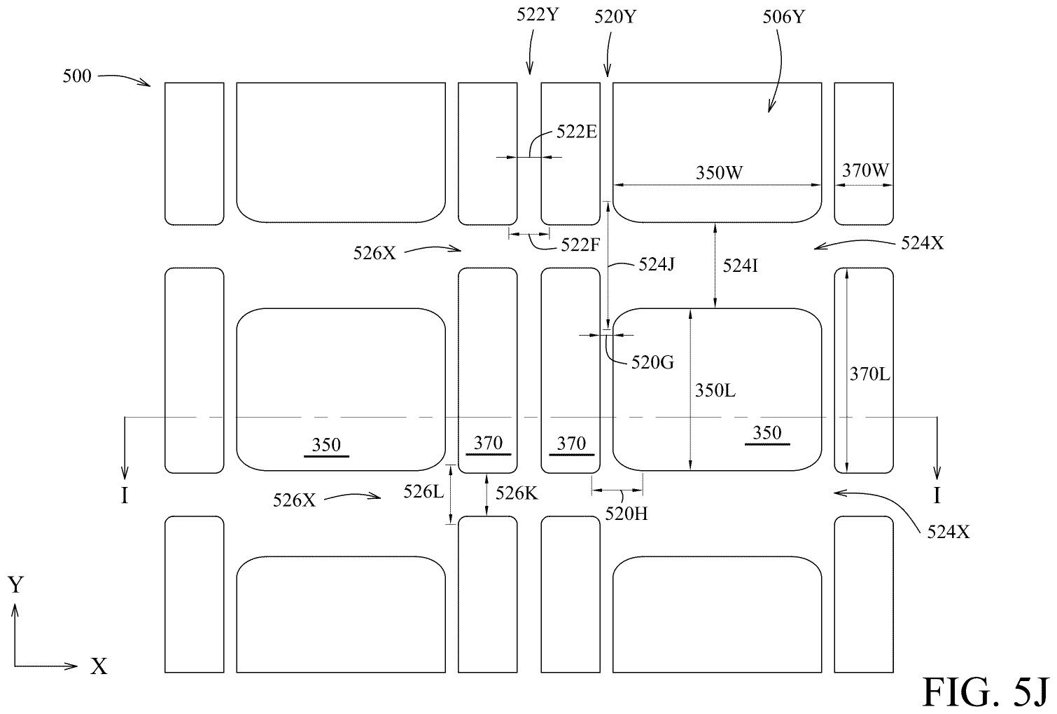

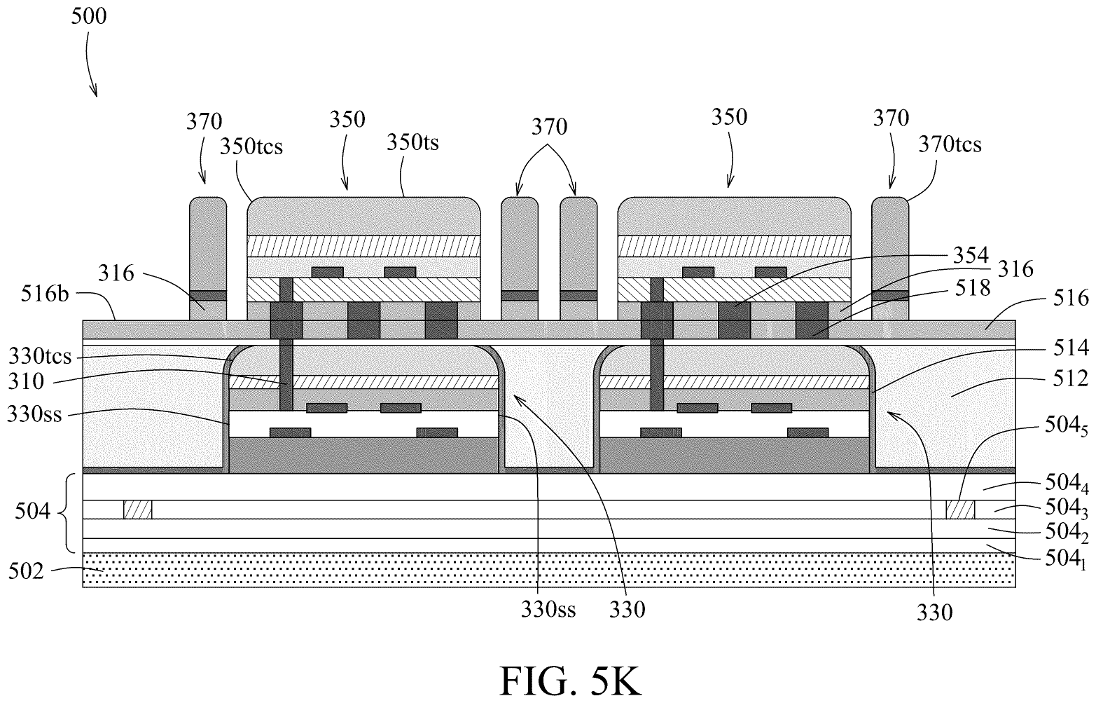

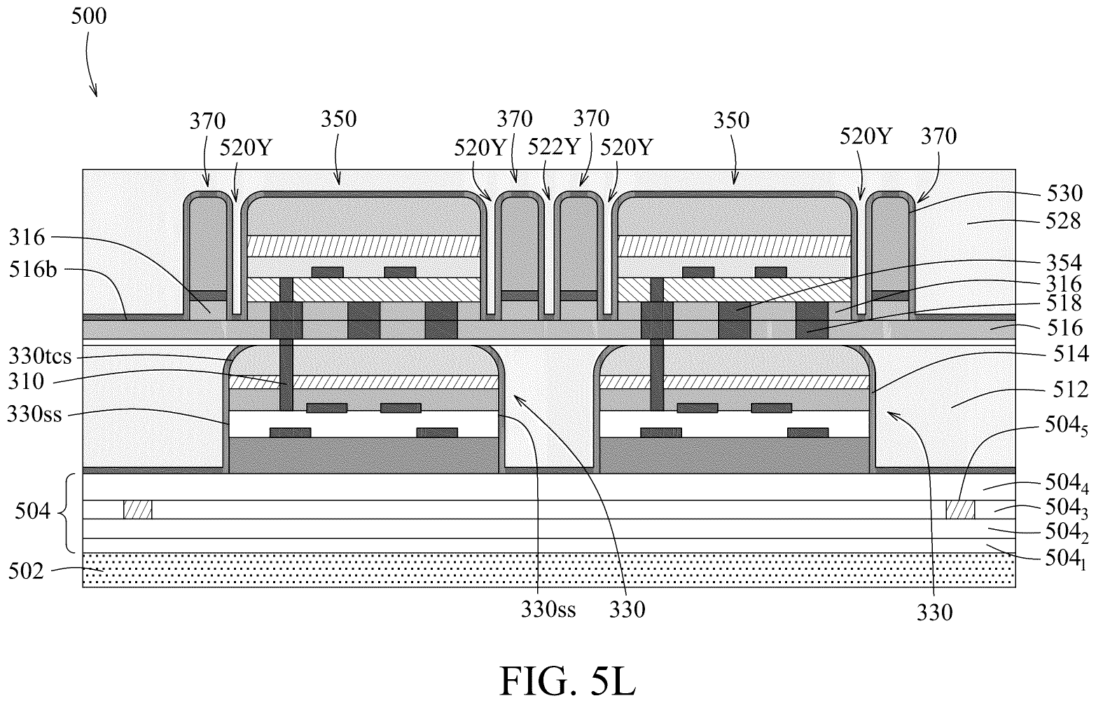

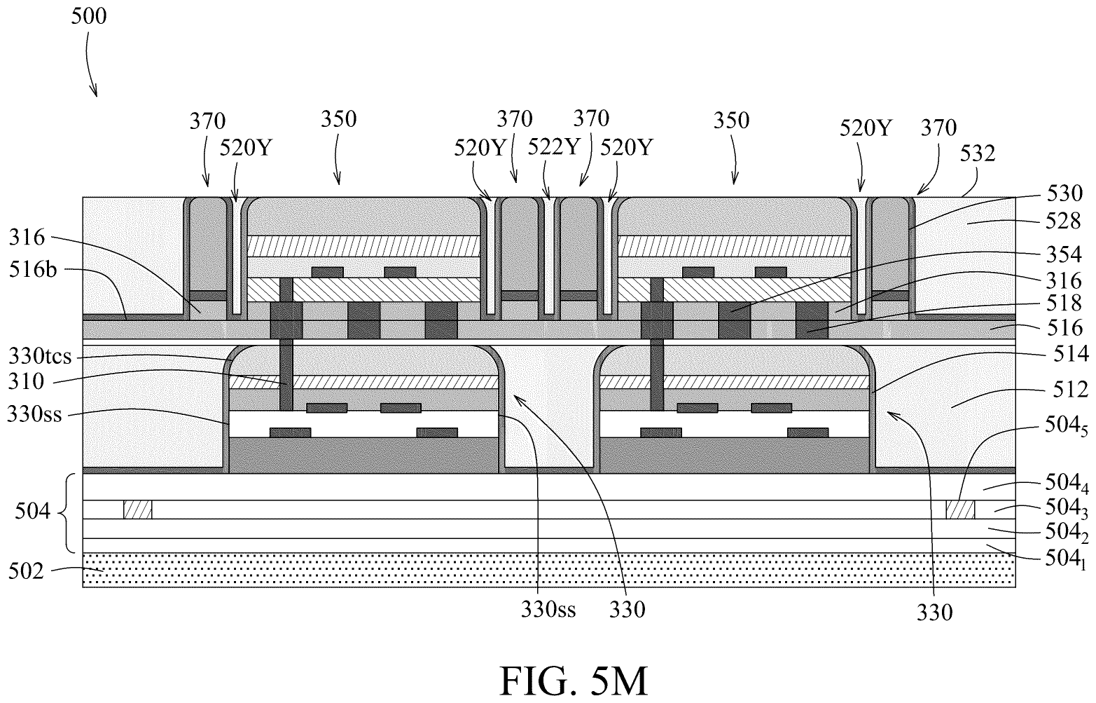

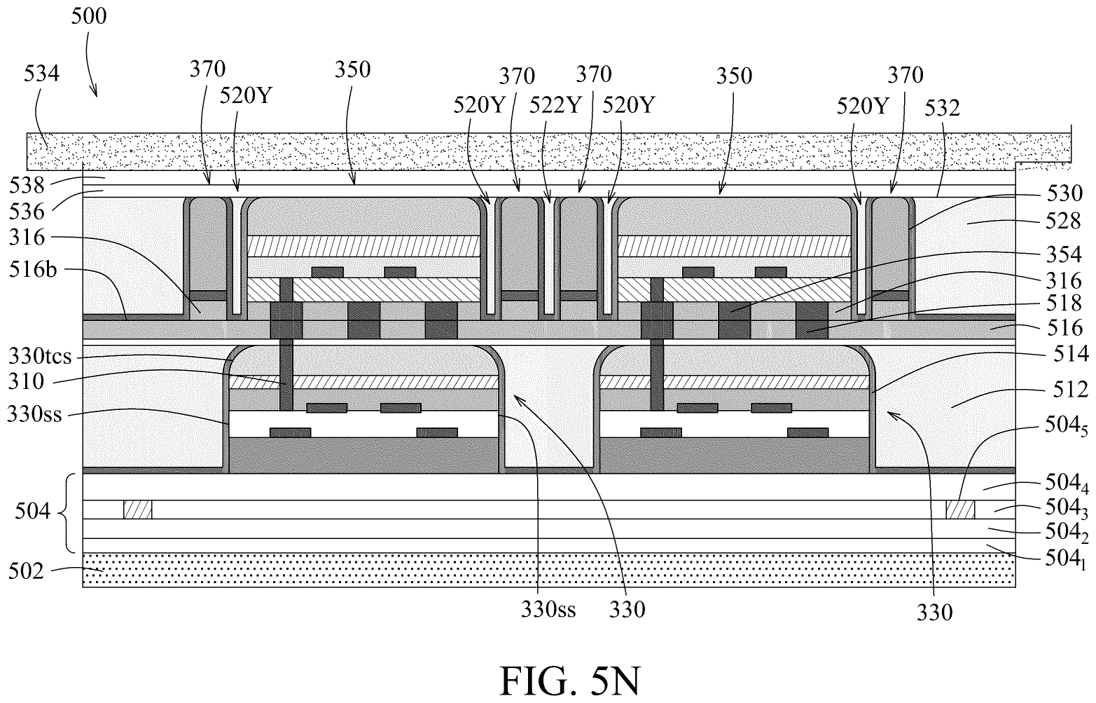

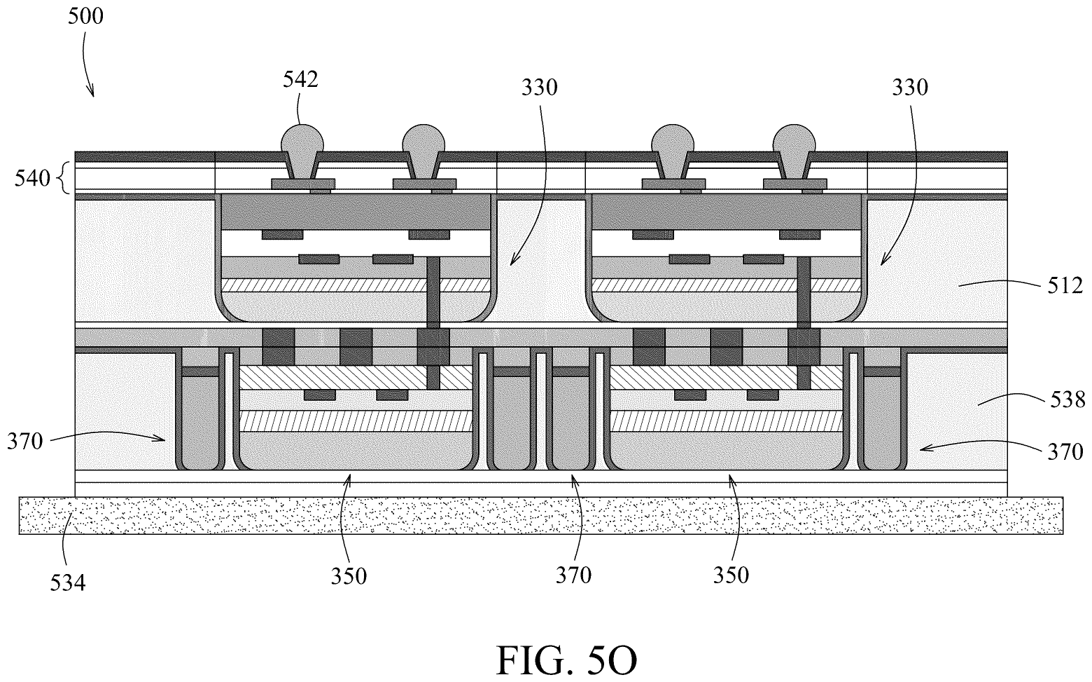

FIG. 5 is a flow diagram illustrating a method 400 of forming of an integrated circuit package according to embodiments of the present disclosure. Dummy dies according to the present disclosure may be used in the method 400. FIGS. 5A-5O schematic demonstrates various processing stages during fabrication of an integrated circuit (IC) package 500 according to embodiments of the present disclosure. The IC package structure 500 may be fabricated using the method 400.

The method 400 may be used to form a 3DIC (three-dimensional integrated circuit) package. In a typical formation process of forming a 3DIC, two layers of dies are vertically stacked, and electrical connections are formed between the two layers of dies. For example, a top die is stacked over a bottom die. The top die and the bottom die may have different dimensions. Dummy dies may be used to make up the dimension difference between the top die and the bottom dies. In the method 400, a larger bottom die is bonded to a smaller top die and one or more dummy dies. It should be noted that the terms “top die” and “bottom die” are used for clarity in description, and not necessarily referred to the physical position of the dies.

In operation 402, one or more dies 330 are attached to a carrier wafer 502, as shown in FIG. 5A. FIG. 5A is a schematic cross-sectional view of the IC package structure 500 after operation 402. The first die 330 may be referred to as a bottom die. The first dies 330 are attached to the carrier wafer 502 via a bonding film 504. In some embodiments, the IC package structure 500 is similar to the IC package 100 described above.

In some embodiments, the first die 330 may include a logic chip. e.g., central processing unit (CPU), graphics processing unit (GPU), system-on-a-chip (SoC), application processor (AP), microcontroller, etc.), an application-specific integrated circuit (ASIC) chip, an analog chip, a sensor chip, a wireless application chip (e.g., a Bluetooth chip, a radio frequency chip, etc.), or a voltage regulator chip. In some embodiments, the first die 330 is a CPU chip.

The carrier wafer 502 may comprise, for example, glass, silicon oxide, aluminum oxide, and the like. The bonding film 504 is applied to the carrier wafer 502. Alternatively, the carrier wafer 502 may comprise a carrier tape. The bonding film 504 may include multiple layers. In some embodiments, the adhesive layer 504 may include an interlayer dielectric layer 504₁ facing the carrier wafer 502, a silicon nitride layer 504₂ formed above the interlayer dielectric layer 504₁, an oxide layer 504₃ formed over the silicon nitride layer 504₂, and a silicon oxynitride (SiON) layer formed over the oxide layer 504₃. In some embodiments, alignment marks 5045 are formed in the bonding film 504, for example formed in the oxide layer 5043.

The first dies 330 are turned over with the bonding film 316 facing the bonding film 504 over the carrier wafer 502. The first dies 330 are attached to the carrier wafer 502 by joining the bonding film 316 and the bonding film 502. The first dies 330 may be positioned on the bonding film 504 one by one. In some embodiments, the first dies 330 are arranged in an array on the carrier wafer 502, as shown in FIG. 5B, which is a partial cross sectional view of the IC package structure 500 showing the arrangement of the first dies 330. As shown in FIG. 5B, the first dies 330 are separated by trenches 506x along the x-direction and trenches 506Y along the y-direction.

As shown in FIG. 5B, the die 330 has a substantially rectangular die area. In some embodiments, when the die 330 is positioned in a bottom layer of a packaging structure, the width 330w of the die 330 is in a range between about 5 mm to about 7 mm, and the length 330L of the die 330 is in a range between about 8 mm to about 12 mm. The radius of curvature R₃₃₀ of the curved side surfaces 330cs is in a range between about 0.3 microns and about 1.5 microns.

Because the first dies 330 include rounded corners, the trenches 506X and 506Y may vary in widths. For example, the trenches 506X and 506Y may be wider near the rounded corners or curved side surfaces 330cs of the dies 330. As shown in FIG. 5B, the trenches 506X have a normal width 506A between the side surfaces 330ss and an extended width 506B near the curved surfaces 330cs. In some embodiments, the normal width 506A is in a range between about 195 microns and about 205 microns. The extended width 506B is greater than the normal width 506A for about 0.5 micron to about 3.0 microns. The extended width 506B is in a range between about 195.5 microns and about 208 microns. The trenches 506Y have a normal width 506C between the side surfaces 330ss and an extended width 506D near the curved surfaces 330cs. In some embodiments, the normal width 506C is in a range between about 80 microns and about 90 microns. The extended width 506D is greater than the normal width 506C for about 0.5 micron to about 3.0 microns. The extended width 506D is in a range between about 80.5 microns and about 93 microns.

As shown in FIG. 5A, the trenches 506X and 506Y have substantially the same width along the z-direction. The semiconductor substrate 302 in the dies 330 has a thickness T₃₀₂ in a range between about 100 microns.

In operation 404, a back grinding process is performed to reduced thickness of the semiconductor substrate 302, as shown in FIG. 5C. After the back grinding process, the semiconductor substrate 302 on the first dies 330 have a reduced thickness T′₃₀₂. In some embodiments, the reduced thickness T′₃₀₂ is about 13.5 microns.

In some embodiments, a top edge rounding process is performed to round edges between the top surface 330ts and the side surfaces 330ss, as shown in FIG. 5D. The top edge rounding process may be performed by any suitable methods. In some embodiment, the top edge rounding process may be performed by a laser source 332. For example, the laser source 508 may move along perimeters of the dies 330 to cut the materials at the edge of die areas.

In another embodiments, the top edge rounding process may be achieved by an anisotropic etching process after the back grinding process. For example, an anisotropic etch process is performed to remove the exposed corners. In some embodiments, a photolithographic mask 510 may be formed to cover substantially the dies 330 with the edges between the top surface 330ts and the side surfaces 330ss exposed, as shown in FIG. 5E.

As shown in FIGS. 5D and 5E, after the top edge rounding process, the die 330 includes curve surfaces 330tcs connecting between side surfaces 330ss and the top surface 330ts. The curved surfaces 330tcs may reduce cracking in the gap filling material between the top layer and bottom layer of dies. In some embodiments, the curve surfaces 330tcs have a width 330bw along the plane of the top surface 330ts, or the x-direction, and a height 330bh along the plane of the side surfaces 330ss, or the z-direction. In some embodiments, the width 330bw may be in a range between about 0.3 microns and about 1.5 microns. In some embodiments, the height 330bh may be in a range between about 0.3 microns and about 1.5 microns.

After the top edge rounding process, the trenches 506X and 506Y are widened near the top surfaces 330ts. In some embodiments, the trenches 506X and 506Y are widened in a range between about 0.6 microns and about 3.0 microns. As shown in FIG. 5D, the trenches 506Y may have an extended width 506E at the top surfaces 330ts. In some embodiments, the width 506E is in a range between about 80.5 microns and about 93 microns. Similarly, the trenches 506X may have an extended width near the top surfaces 330ts in a range between about 195.5 microns and about 208 microns.

In operation 406, a gap filling material 512 is filled in the trenches 506X and 506Y, as shown in FIG. 5F. In some embodiments, the gap filling material 512 may be a dielectric material. For example, the gap filling material 512 may include an oxide material, such as TEOS, silicon oxide (SiO), BPTEOS, or the like. The gap filling material 512 may also be a nitride material. The gap filling material 512 may also be a low-k dielectric material, a polymer material, other dielectric material, the like, or combinations thereof. The gap filling material 512 may also be formed by plasma enhanced chemical vapor deposition (PECVD), low pressure CVD (LPCVD), plasma vapor deposition (PVD), or the like.

In some embodiments, a liner layer 514 may be first deposited over the dies 330 and the exposed bonding film 504, prior to depositing the gap filling material 512. In some embodiments, the liner layer 514 may include silicon nitride.

A chemical mechanical polishing (CMP) process may be performed to remove the gap filling material 512 deposited over the first die 330 and to expose substrate 302 in the first die 330, as shown in FIG. 5G. In some embodiments, the TSV structures 310 are also exposed after the CMP process.

Because of the rounded corners or curved surfaces on the dies 330, the trenches 506X and 506Y have wider openings near the top surfaces which improves deposition uniformity of the gap fill material 512.

In operation 408, a bonding film 516 is deposited over the first dies 330 and the gap filling material 512, as shown in FIG. 5H. In some embodiments, the bonding film 516 may be formed of silicon oxide, silicon oxynitride, silicon nitride, or low-k dielectric materials having k values lower than about 3.0. The low-k dielectric materials may include a carbon-containing low-k dielectric material, Hydrogen SilsesQuioxane (HSQ), MethylSilsesQuioxane (MSQ), or the like. In some embodiments, the bonding film 516 may be formed by suitable fabrication techniques such as chemical vapor deposition (CVD), High-Density Plasma Chemical Vapor Deposition (HDPCVD) or plasma-enhanced chemical vapor deposition (PECVD).

In operation 410, bond pad features 518, also referred to as bond pad metals (BPMs) are formed in the bonding film 516, as shown in FIG. 5H. The bond pad features 518 may be formed of copper or other suitable metal to facilitate subsequent bonding. In some embodiments, the bond pad features 518 may be formed by suitable fabrication techniques such as electroplating or deposition. In some embodiments, the bond pad features 518 may be formed by a damascene process, such as a single damascene process or a dual-damascene process. The bond pad features 518 are configured to bond with bond pad features on a second die. The bond pad features 518 are arranged within a region corresponding to the second die and in a pattern matching bond pad features in the second die. In some embodiments, a top surface of the bond pad features 518 and a top surface of the bonding film 516 are substantially coplanar so as to provide an appropriate surface for the subsequent bonding. The planarity may be achieved, for example, through a planarization step such as a chemical mechanical polishing (CMP) step or a mechanical grinding step. After planarization, a substantially planar bonding surface 516b including areas of the bonding film 516 and areas of the bond pad features 518 is formed over the first dies 330.

In some embodiments, a portion of the bond pad features 518 are connected to the TSVs 310 in the first dies 330. The TSVs 310 may be used to provide electrical connection between the first die 330 and a second die to be bonded to the first die 330.

In operation 412, one or more second dies 350 and one or more dummy dies 370 are bonded to the first die 330, as show in FIGS. 5I and 5J. FIG. 5I is a schematic cross-sectional view of the IC package structure 500 after operation 410. FIG. 5J is a plane view of the IC package structure 500 along J-J line on FIG. 5I.

In some embodiments, the second dies 350 may be referred to as top dies. The second die 350 may include a memory chip such as a high bandwidth memory chip, a dynamic random access memory (DRAM) chip or a static random access memory (SRAM) chip.

In some embodiments, the first dies 330 and the second dies 350 may be bonded face-to-face as shown FIG. 5I. The bonding film 316 of the second die 350 is bonded to the bonding film 516 formed over the first die 330 through the dielectric-to-dielectric bonding, and the bond pad features 354 of the second die 350 are bonded to the bond pad features 518 over the first die 330 through the metal-to-metal bonding. The bonding process may be referred to as D-D and M-M bonding.

Before bonding the second die 350 to the first die 330, the second die 350 may be picked-up and placed onto a bonding surface 518b above the first die 330 such that the bonding surface 516b above the first die 330 is in direct contact with the second die 350, and the bond pad features 518 and 516 are aligned and in direct contact. In some embodiments, to facilitate the D-D and M-M bonding between the bonding film 516 and the second die 350, surface preparation for the bonding surfaces of the first die 330 and second die 350 may be performed. The surface preparation may include surface cleaning and activation, for example. In some embodiments, the bonding surface 516b of the first die 330 and the bonding surface of the second die 350 may be cleaned by wet cleaning.

After bonding, a D-D and M-M bonding surface is formed between the bonding film 516 and the second die 350. In some embodiments, the metal-to-metal bonding at the D-D and M-M bonding interface is copper-to-copper bonding. In some embodiments, the dielectric-to-dielectric bonding at the D-D and M-M bonding interface is achieved with Si—O—Si bonds generated. After bonding, the first die 330 is electrically connected to the second die 350 by the bonding between the bond pad features 516 and the bond pad features 518. During the D-D and M-M bonding process, a low temperature heating process at a temperature range between about 100° C. and about 280° C. is performed to strengthen the dielectric-to-dielectric bonding at the D-D and M-M bonding interface. A high temperature heating process is performed at a temperature in a range between about 100° C. and about 400° C. to facilitate the metal-to-metal bonding at the D-D and M-M bonding interface.

Before bonding the dummy dies 370 to the first die 330, the dummy dies 370 may be picked-up from a frame and placed onto the bonding surface 516b over the first die 330 such that the bonding surface 516b over the first die 330 is in direct contact with the bonding film 316 of the dummy die 370.

The dummy dies 370 are stacked on the first die 330 and bonded thereon. The dummy dies 370 are disposed side-by-side with each other and with the second die 350. In some embodiments, the dummy dies 370 are fusion-bonded with the bonding film 516 over the first die 330. In other words, the dummy dies 370 are bonded with the bonding film 516 over the first die 330 through dielectric-to-dielectric bonding In some embodiment, dummy die 370 bonded with the bonding film 516 over the first die 330 without having any metal-metal bonding.

As shown in FIGS. 5I and 5J, the second die 350 is smaller than the first die 330. One or more dummy dies 370 are bonded over the first die 330 so that the bottom layer and the top layer are substantially the same size. FIGS. 5I and 5J depicts two dummy dies 370 disposed adjacent one second die 350 and over the first die 330. Less or more dummy dies 370 may be included depending on the design of the IC package structure 500.

Shape and dimension of each dummy die 370 may be selected according to the shapes, dimensions, and relative position of the first die 330 and the second die 350. The surface area of each dummy die 370 may be selected according to the surface area of the larger die or the first die 330 in the IC package structure 500. In some embodiments, a ratio of the surface area of each dummy die 370 over the surface area of the first die 330 may be in a range between about 7.5% and about 10%. The shape of the dummy dies 370 may be rectangular, square, or other shapes conform with the layout. In some embodiments, a top surface of the dummy die 370 and a top surface of the second die 350 are substantially coplanar. In some embodiment, the top surface of the dummy die 370 is lower than the top surface of the second die 350. Alternatively, the top surface of the dummy die 370 is higher than the top surface of the second die 350.

As shown in FIG. 5J, each of the die 350 and the dummy die 370 has a substantially rectangular die area. In some embodiments, when the die 350 has a width 350w along the x-direction and a length 350L along the y-direction. In some embodiments, the width 350w is in a range between about 3 mm to about 6 mm, and the length 350L is in a range between about 3 mm to about 7 mm. The radius of curvature R₃₅₀ of the curved side surfaces 350cs is in a range between about 0.3 microns and about 1.5 microns. In some embodiments, when the dummy die 370 has a width 370w along the x-direction and a length 370L along the y-direction. In some embodiments, the width 370w is in a range between about 0.5 mm to about 3 mm, and the length 370L is in a range between about 8 mm to about 12 mm. The radius of curvature R₃₇₀ of the curved side surfaces 350cs is in a range between about 0.3 microns and about 1.5 microns.

The die 350 is positioned over the die 330 and the dummy dies 370 are positioned on adjacent the die 350. After the dies 350 and the dummy dies 370 are bonded to the bonding film 516, trenches 520Y are formed between the die 350 and the dummy die 370 along the y-direction; trenches 522Y are formed between two neighboring dummy dies 370 along the y-direction; trenches 524X are formed between two adjacent dies 350 along the x-direction; and trenches 526Y are formed between two adjacent dummy dies 370 along the x-direction.

Because the dies 350 and dummy ides 370 include rounded corners, the trenches 520Y, 522Y, 524X, 526X may vary in widths. For example, the trenches 520Y, 522Y, 524X, 526X may be wider near the rounded corners or curved side surfaces of the dies 350 and the dummy dies 370.

As shown in FIG. 5J, the trenches 522Y have a normal width 522E between the side surfaces and an extended width 522F near the curved surfaces or rounded corners. In some embodiments, the normal width 522E is in a range between about 80 microns and about 90 microns. The extended width 522F is greater than the normal width 522E for about 0.5 micron to about 3.0 microns. The extended width 522F is in a range between about 80.5 microns and about 93 microns. The trenches 520Y have a normal width 520G between the side surfaces and an extended width 520H near the curved surfaces or rounded corners. In some embodiments, the normal width 520G is in a range between about 65 microns and about 75 microns. The extended width 520H is greater than the normal width 520G for about 0.5 micron to about 3.0 microns. The extended width 520H is in a range between about 65.5 microns and about 78 microns. The trenches 524X have a normal width 524I between the side surfaces and an extended width 524J near the curved surfaces or rounded corners. In some embodiments, the normal width 524I is in a range between about 545 microns and about 555 microns. The extended width 524J is greater than the normal width 524I for about 0.5 micron to about 3.0 microns. The extended width 522J is in a range between about 545.5 microns and about 558 microns. The trenches 526X have a normal width 526K between the side surfaces and an extended width 526L near the curved surfaces or rounded corners. In some embodiments, the normal width 526K is in a range between about 195 microns and about 205 microns. The extended width 526L is greater than the normal width 526K for about 0.5 micron to about 3.0 microns. The extended width 526L is in a range between about 195.5 microns and about 208 microns.

In operation 414, a back grinding process is performed to reduced thickness of the semiconductor substrate 302 in the dummy dies 370 and the dies 350, as shown in FIG. 5K. The operation 414 may be similar to the grinding process in operation 404. After the back grinding process, the semiconductor substrate 302 on the second dies 350 have a reduced thickness T′₃₀₂. In some embodiments, the reduced thickness T′₃₀₂ is about 13.5 microns. The dummy dies 370 are grinded to the same level as the second dies 350.

Similar to in the operation 404 described above, a top edge rounding process is performed to round edges between the top surface and side surfaces in of the dummy dies and the second dies 350, as shown in FIG. 5K. After the top edge rounding process, the dies 350 includes curve surfaces 350tcs connecting between side surfaces 350ss and the top surface 350ts. The curved surfaces 350tcs may reduce cracking in the subsequently formed gap filling material. In some embodiments, the curved surfaces 350tcs have a width in a range between about 0.3 microns and about 1.5 microns along the x-direction and a height in a range between about 0.3 microns and about 1.5 microns along the z-direction. In some embodiments, top edges of the dummy dies 370 may be also rounded.

After the top edge rounding process, the trenches 520Y, 522Y, 524X and 526X are widened near the top surfaces 350ts. In some embodiments, the trenches 520Y, 522Y, 524X and 526X are widened in a range between about 0.6 microns and about 3.0 microns.

In operation 416, a gap fill material 528 is deposited over the IC package structure 500 to fill gaps between the dummy dies 370 and the second die 350, as shown in FIG. 5L. In some embodiments, the gap fill material 528 may include a dielectric material. For example, the gap fill material 528 may include an oxide material, such as silicon oxide (SiO), TEOS, BPTEOS, or the like. The dielectric film 446 may also be a nitride material. The gap fill material 528 may also be a low-k dielectric material, a polymer material, other dielectric material, the like, or combinations thereof. The gap fill material 528 may also be formed by plasma enhanced chemical vapor deposition (PECVD), low pressure CVD (LPCVD), plasma vapor deposition (PVD), or the like. In some embodiments, a liner layer 530 may be deposited prior to depositing the gap fill material 528. In some embodiments, the liner layer 530 includes silicon nitride.

In operation 418, a planarization process is performed, as shown in FIG. 5M. The planarization process removes excess gap fill material 528 over the dummy dies 370 and the second die 350. The planarization process may also be used to thin down the dummy dies 370 and the second die 350 and to generate a planar surface 532 for further process, for example processes to stacking another layer of dies and forming bond pad features. In some embodiment, when the top surface of the dummy die 370 is lower than the top surface of the second die 350, the top surface of the dummy die 370 is covered by the gap filling material after the planarization process. Alternatively, when the top surface of the dummy die 370 is higher than the top surface of the second die 350, the top surface of the second die 350 is covered by the gap filling material after the planarization process.

In operation 420, a second carrier wafer 534 is attached to the IC package structure 500 on the planar surface 532, as shown in FIG. 5N. In some embodiments, a bonding film 538 is formed over the second carrier wafer 534. A bonding film 536 is formed over the planar surface 532 of the IC package structure 500. In some embodiments, the bonding films 536, 538 is formed of an oxide material. For example, the bonding films 536, 538 may include a dielectric material, such as silicon oxide, silicon oxynitride, or the like.

The IC package structure 500 is attached to second carrier wafer 534 by bonding the bonding films 536, 538. After the second carrier wafer 534 is attached to the IC package structure 500, the first carrier wafer 502 may be removed, and the IC package structure 500 flipped over to form contacts over the front side of the first die 330. In some embodiments, a surface preparation, such as surface cleaning and activation, may be performed to expose a topmost layer of the conductive features on the first dies 330 for subsequent processing.

In operation 422, a RDL (redistribution layer) structure 540 and external connectors 542 are formed over the first dies 330, as shown in FIG. 5O. The RDL structure 540 may comprise one or more conductive layers formed in on or more passivation layers. The conductive layers may include metals such as aluminum, copper, tungsten, titanium, and combinations thereof. The RDL structure 540 may be formed by depositing the conductive layers through chemical vapor deposition and then etching the undesired portions, leaving the RDL structure 540. Other materials and process, such as a well-known damascene process, could alternatively be used to form the RDL structure 540.

The external connectors 542 may be contact bumps such as micro bumps or controlled collapse chip connection (C4) bumps. The external connectors 542 may comprise a material such as tin, or other suitable materials, such as silver or copper. In some embodiments, the external connectors 542 are tin solder bumps formed by any suitable method such as evaporation, electroplating, printing, solder transfer, ball placement, etc. Once a layer of tin has been formed on the structure, a reflow is performed in order to shape the material into the desired bump shape.

Embodiments of the present disclosure provide IC dies with rounded corners. In some embodiments, the IC die is a SOIC (system on integrated chip). The rounded corners prevent tip discharge which may adversely affect circuit structure of the SOIC. The IC dies with the rounded corners improve quality of gap filling material in IC packages, for example, reducing cracks in the gap filling material.

It will be understood that not all advantages have been necessarily discussed herein, no particular advantage is required for all embodiments or examples, and other embodiments or examples may offer different advantages.

Some embodiments of the present disclosure relate to a semiconductor package comprising: a first die having: a first side surface; a second side surface; a first curved surface connecting the first side surface and the second side surface; a first top surface; a second curved surface connecting the first side surface and the first top surface; and a second die having: a third side surface facing the first side surface of the first die; a fourth side surface; and a third curved surface connecting the third side surface and the fourth side surface; and a first gap fill material disposed between the first side surface and the third side surface.

Some embodiments of the present disclosure relate to a method comprising placing a first die adjacent a second die, wherein the first die includes: a first side surface; a second side surface; a first curved surface connecting the first side surface and the second side surface; and a second die having: a third side surface facing the first side surface of the first die; a fourth side surface; and a second curved surface connecting the third side surface and the fourth side surface; and filling a gap between the first die and the second die with a gap fill material.

Some embodiments of the present disclosure relate to a method for forming integrated circuit dies, comprises: forming a bonding film on a semiconductor substrate; forming a dicing pattern over the bonding film, wherein the dicing pattern includes a plurality of dice areas, and each of the dice area has a rectangular shape with rounded corners; etching through the bonding film into the semiconductor substrate using the dicing pattern to form dicing trenches around the dice areas; depositing a protection layer in the dicing trenches and on the bonding film; attaching a carrier wafer to the protection layer; and grinding the semiconductor substrate from a back side to expose the protection layer in the dicing trenches.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor package, comprising:
a first die having:
a first side surface;
a second side surface;
a first curved surface connecting the first side surface and the second side surface;
a first top surface;
a second curved surface connecting the first side surface and the first top surface; and
a second die having:
a third side surface facing the first side surface of the first die;
a fourth side surface; and
a third curved surface connecting the third side surface and the fourth side surface; and
a first gap fill material disposed between the first side surface and the third side surface.

2. The semiconductor package of claim 1, wherein the first top surface comprises a semiconductor material.

3. The semiconductor package of claim 1, wherein the first curved surface has a radius of curvature in a range between about 0.3 microns and about 1.5 microns.

4. The semiconductor package of claim 1, further comprising a third die disposed over the top surface of the first die, wherein the third die includes:
a fifth side surface;
a sixth side surface;
a fourth curved surface connecting the fifth side surface and the sixth side surface; and
a bottom surface facing the first die.

5. The semiconductor package of claim 4, wherein the third die has a second top surface parallel to the bottom surface; and
a fifth curved surface connecting the fifth side surface and the second top surface.

6. The semiconductor package of claim 5, further comprising a fourth die disposed adjacent the third die, wherein the fourth die has
a seventh side surface facing the fifth side surface;
an eighth side surface; and
a sixth curved surface connecting the seventh side surface and the eighth side surface.

7. The semiconductor package of claim 6, further comprising:
a second gap fill material disposed between the seventh side surface and the fifth side surface.

8. The semiconductor package of claim 6, wherein the fourth die is a dummy die.

9. The semiconductor package of claim 4, further comprising:
a bonding film disposed between the first die and second third die.

10. A method, comprising:
placing a first die adjacent a second die, wherein the first die includes:
a first side surface;
a second side surface;
a first curved surface connecting the first side surface and the second side surface; and
a second die having:
a third side surface facing the first side surface of the first die;
a fourth side surface; and
a second curved surface connecting the third side surface and the fourth side surface; and
filling a gap between the first die and the second die with a gap fill material.

11. The method of claim 10, further comprising: prior to filling the gap with the gap fill material,
grinding the first die and the second die so that the first die has a first top surface and the second has a second top surface; and
rounding edges of the first top surface and the second top surface.

12. The method of claim 10, wherein the first curved surface has a radius of curvature in a range between about 0.3 microns and about 1.5 microns.

13. The method of claim 11, further comprising:
forming a bonding film over the first die, the second die and the gap fill material; and
bonding a third die to the bonding film, wherein the third die is stacked over the first die and includes curved side surfaces.

14. The method of claim 12, further comprising:
bonding a dummy die to the bonding film, wherein the dummy die is adjacent to the third die.

15. A method for forming integrated circuit dies, comprises:
forming a bonding film on a semiconductor substrate;
forming a dicing pattern over the bonding film, wherein the dicing pattern includes a plurality of dice areas, and each of the dice area has a rectangular shape with rounded corners;
etching through the bonding film into the semiconductor substrate using the dicing pattern to form dicing trenches around the dice areas;
depositing a protection layer in the dicing trenches and on the bonding film;
attaching a carrier wafer to the protection layer; and
grinding the semiconductor substrate from a back side to expose the protection layer in the dicing trenches.

16. The method of claim 15, further comprising: prior to forming the bonding film on the semiconductor substrate,
forming a device layer on the semiconductor substrate; and
forming an interconnect structure over the device layer.

17. The method of claim 16, wherein forming the device layer comprises:
forming one or more device masks including patterning features arranged in rectangular areas with rounded corners.

18. The method of claim 16, wherein forming the interconnect structure comprises:
forming one or more interconnect masks including patterning features arranged in rectangular areas with rounded corners.

19. The method of claim 15, further comprising:
attaching an expansion tape to the back side of the semiconductor substrate after grinding the semiconductor substrate; and
stretching the expansion tape to widen the dicing trenches.

20. The method of claim 19, further comprising:
removing the protection layer to expose the bonding film.
